(19) United States
(12) Patent Application Publication
(10) Pub. No.: US 2025/0338779 A1
(43) Pub. Date: Oct. 30, 2025

(54) LATTICE-MATCHED OXIDE LAYER AS TUNNEL BARRIER FOR PERPENDICULARLY MAGNETIZED HEUSLER COMPOUNDS

(71) Applicants: International Business Machines Corporation, Armonk, NY (US); Samsung Electronics Co., Ltd., Gyeonggi-Do (KR)

(72) Inventors: Chirag Garg, San Jose, CA (US); Panagiotis Charilaos Filippou, Fremont, CA (US); See-Hun Yang, Morgan Hill, CA (US); Dmytro Apalkov, San Jose, CA (US); Jaewoo Jeong, Los Altos, CA (US); Fnu Ikhtiar, San Jose, CA (US); Roman Chepulskyy, Santa Clara, CA (US); Mahesh Samant, San Jose, CA (US)

(21) Appl. No.: 18/645,353

(22) Filed: Apr. 24, 2024

(51) Int. Cl. H10N 50/85; H10B 61/00; H10N 50/01

(52) U.S. Cl. CPC H10N 50/85; H10B 61/00; H10N 50/01

(57) ABSTRACT

A magnetoresistive random-access memory cell includes a first magnetic layer having a first lattice constant; a second magnetic layer having a second lattice constant; and a tunnel barrier between the first and second magnetic layers. The tunnel barrier includes at least one oxide layer with an oxide layer lattice constant. The oxide layer lattice constant has a mismatch smaller than six percent with at least one of the first and second lattice constants.

### BACKGROUND

The present invention relates generally to the electrical, electronic and computer arts and, more particularly, to magnetoresistive random-access memory (MRAM).

Current MRAM devices use a magnetic tunnel junction (MTJ) as a storage element. A simple MTJ is a tri-layer structure containing two magnetic layers separated by a tunnel barrier layer. The magnetic state of one of the layers (the so-called free-layer or storage layer) has a bi-stable magnetization direction that can be switched using Spin Transfer Torque (STT). Thus, current MRAMs are three-layer devices employing a magnetic tunnel junction (MTJ). They typically include a reference layer magnet, a tunnel barrier, and a storage or free magnetic layer. The magnetic layer can either be a ferromagnet or a ferrimagnet. Current is passed through the device and the resistance is measured. The resistance changes based on the magnetic orientation of the two magnetic layers, and the relative change in resistance is referred to as the tunnel magnetoresistance (TMR), which is related to the spin polarization (i.e., high spin polarization implies high TMR). High spin polarization, and thus high TMR, is desirable (higher TMR provides a higher ON/OFF ratio). Low switching current is also desirable. The switching current is proportional to the product (Mₛ V Hₖ) where Mₛ is saturation magnetization, V is volume, and Hₖ is anisotropy field.

In a parallel configuration (e.g., storing a zero), the magnetic layers have their magnetizations aligned with each other; the resistance is typically lower in this state relative to the anti-parallel configuration (e.g., storing a one). In the anti-parallel state, the magnetic layers do not have their magnetizations aligned with each other; the resistance is typically higher in this state relative to the parallel configuration. The magnetic state of the MTJ is changed by passing a current through it. The current delivers spin angular momentum, so that once a threshold current is exceeded, the direction of the memory layer moment is switched. Since these MRAM devices are switched using STT, they are referred to as STT-MRAM. The magnitude of the switching current that is required is less when the magnetization of the electrodes is oriented perpendicular to the layers. The magnetic layers have magnetization perpendicular to the film surface (i.e. have perpendicular magnetic anisotropy (PMA)) as smaller switching currents are needed than for in-plane magnetized MTJs. MTJs with magnetic layers having PMA need smaller switching current than for in-plane magnetized layers.

Current devices employ alloys of cobalt, iron, and boron for the magnetic layers and these layers are ferromagnetic (such current devices do not scale well to smaller sizes). Heusler compounds are magnetic intermetallics with a face-centered cubic (FCC) crystal structure and a composition of X₂YZ (full-Heuslers or simply “Heuslers”), where X and Y are transition metals and Z is in the p-block (or main group) of the periodic table. Half Heuslers have the composition XYZ. Reference herein to Heusler or Heuslers without the term “half” is intended to reference full-Heuslers. Heusler compounds have four interpenetrating FCC sublattices. CoFeB devices typically need interface anisotropy for PMA, while Heusler compounds typically are PMA due to volume anisotropy.

### BRIEF SUMMARY

Principles of the invention provide lattice-matched oxide layer as tunnel barrier for perpendicularly magnetized Heusler compounds. In one aspect, an exemplary magnetoresistive random-access memory cell includes a first magnetic layer having a first lattice constant; a second magnetic layer having a second lattice constant; and a tunnel barrier between the first and second magnetic layers, where the tunnel barrier includes at least one oxide layer with an oxide layer lattice constant, and where the oxide layer lattice constant has a mismatch smaller than six percent with at least one of the first and second lattice constants.

In still another aspect, a magnetoresistive random-access memory array of such magnetoresistive random-access memory cells includes a plurality of bit lines and a plurality of complementary bit lines forming a plurality of bit line-complementary bit line pairs; a plurality of word lines intersecting the plurality of bit line pairs at a plurality of cell locations; and a plurality of magnetoresistive random-access memory cells located at each of the plurality of cell locations. Each of the magnetoresistive random-access memory cells is electrically connected to a corresponding bit line and selectively interconnected to a corresponding one of the complementary bit lines under control of a corresponding one of the word lines. Each of the plurality of magnetoresistive random-access memory cells includes: a first magnetic layer having a first lattice constant; a second magnetic layer having a second lattice constant; and a tunnel barrier between the first and second magnetic layers, where the tunnel barrier includes at least one oxide layer with an oxide layer lattice constant, and where the oxide layer lattice constant has a mismatch smaller than six percent with at least one of the first and second lattice constants.

In a further aspect, a method of forming a magnetoresistive random-access memory cell includes providing a substrate; forming a first magnetic layer outward of the substrate, the first magnetic layer having a first lattice constant; forming a tunnel barrier outward of the first magnetic layer, where the tunnel barrier includes at least one oxide layer with an oxide layer lattice constant; and forming a second magnetic layer outward of the tunnel barrier, the second magnetic layer having a second lattice constant; where the oxide layer is formed such that the oxide layer lattice constant has a mismatch smaller than six percent with at least one of the first and second lattice constants.

In yet a further aspect, a hardware description language (HDL) design structure is encoded on a machine-readable data storage medium. The HDL design structure includes elements that when processed in a computer-aided design system generate a machine-executable representation of a magnetoresistive random-access memory cell and/or array, as described.

As used herein, “facilitating” an action includes performing the action, making the action easier, helping to carry the action out, or causing the action to be performed. Thus, by way of example and not limitation, instructions executing on one processor might facilitate an action carried out by semiconductor processing equipment, by sending appropriate data or commands to cause or aid the action to be performed. Where an actor facilitates an action by other than performing the action, the action is nevertheless performed by some entity or combination of entities.

Techniques as disclosed herein can provide substantial beneficial technical effects, as will be discussed further below. Features and advantages will become apparent from the following detailed description of illustrative embodiments thereof, which is to be read in connection with the accompanying drawings.

### BRIEF DESCRIPTION OF THE DRAWINGS

The following drawings are presented by way of example only and without limitation, wherein like reference numerals (when used) indicate corresponding elements throughout the several views, and wherein:

FIG. 1 presents tables of Heusler compounds and magnesium oxide and a mismatch formula;

FIG. 2 shows aspects of mismatch between MgO and Mn₃Ge layers;

FIG. 3 shows in-plane lattice constants for four indicated Heusler materials and three indicated oxide materials;

FIG. 4 shows a Heusler compound employed in aspects of the invention;

FIG. 5 shows growth of a Heusler compound on a templating layer according to aspects of the invention;

FIGS. 6-8 show various templating layer candidates;

FIGS. 9A-14B show exemplary MRAM cells, according to aspects of the invention;

FIG. 15 shows an array of MRAM cells, according to an aspect of the invention;

FIG. 16 depicts a computing environment according to an embodiment of the present invention (e.g., for implementing a design process such as that of FIG. 17);

FIG. 17 is a flow diagram of a design process used in semiconductor design, manufacture, and/or test;

FIG. 18 shows an exemplary cell using of Fe₃X as a top-chemical templating layer (T-CTL), according to aspects of the invention;

FIG. 19 shows an exemplary cell using Fe₃X as a top CTL enabling a Heusler compound based STT switchable MTJ, according to aspects of the invention; and

FIG. 20 shows the dependence of coercivity on Heusler layer thickness, for an example stack, according to an aspect of the invention.

It is to be appreciated that elements in the figures are illustrated for simplicity and clarity. Common but well-understood elements that may be useful or necessary in a commercially feasible embodiment may not be shown in order to facilitate a less hindered view of the illustrated embodiments.

### DETAILED DESCRIPTION

Principles of inventions described herein will be in the context of illustrative embodiments. Moreover, it will become apparent to those skilled in the art given the teachings herein that numerous modifications can be made to the embodiments shown that are within the scope of the claims. That is, no limitations with respect to the embodiments shown and described herein are intended or should be inferred.

Given the discussion herein, it will be appreciated that in one aspect, an exemplary magnetoresistive random-access memory cell includes a first magnetic layer having a first lattice constant; a second magnetic layer having a second lattice constant; and a tunnel barrier between the first and second magnetic layers, where the tunnel barrier includes at least one oxide layer with an oxide layer lattice constant, and where the oxide layer lattice constant has a mismatch smaller than six percent with at least one of the first and second lattice constants. Technical benefits include providing a structure with alternate tunnel barrier materials (e.g., as compared to MgO) with better lattice matching to, e.g., tetragonal Heusler compounds to achieve their full potential for use in MRAMs and the like; use of oxides that have a small lattice mismatch with, e.g., tetragonal Heusler compounds which helps to preserve the tetragonal structure of Heusler compounds, which provides large magnetic anisotropy; use of oxides that have a small lattice mismatch with, e.g., tetragonal Heusler compounds which reduces lattice dislocations in Heusler compounds, especially near the interface, leading to better magnetic uniformity and potentially high TMR ratio.

In some cases, the magnetoresistive random access memory cell further includes a templating layer, where at least one of the magnetic layers comprises a perpendicularly-magnetized Heusler compound grown on the templating layer, where the oxide layer lattice constant has the mismatch smaller than six percent with the at least one of the magnetic layers that comprises the perpendicularly-magnetized Heusler compound grown on the templating layer. Technical benefits include templating layers that facilitate growth of the Heusler material to more closely match the lattice constant of the alternate tunnel barrier.

In some instances, the at least one of the magnetic layers that includes the perpendicularly-magnetized Heusler compound grown on the templating layer includes a free layer. Technical benefits include PMA, low moment due to ferrimagnetic configuration, and large magnetic anisotropy.

In some instances, the tunnel barrier includes only the at least one oxide layer. Technical benefits include a simple way to fabricate the tunnel barrier.

In some such instances, the first magnetic layer and the second magnetic layer each include a perpendicularly-magnetized Heusler compound. Technical benefits include fabrication using readily available Heusler compounds.

Note that generally, one and optionally both Heusler layers can be grown on a templating layer.

In some instances, the first magnetic layer and the second magnetic layer are selected from the group consisting of Mn₃Ge, Mn₃Sn, Mn₃Sb, Mn₂CoSn, Mn₂FeSb, Mn₂CoAl, Mn₂CoGe, Mn₂CoSi, and Mn₂CuSi. Technical benefits include fabrication using these readily available compounds.

In some embodiments, one of the first magnetic layer and the second magnetic layer includes a perpendicularly-magnetized Heusler compound and another one of the first magnetic layer and the second magnetic layer includes a cubic-based magnetic material. Technical benefits include fabrication using readily available compounds for the layer formation.

In some cases, the one of the first magnetic layer and the second magnetic layer is selected from the group consisting of Mn₃Ge, Mn₃Sn, Mn₃Sb, Mn₂CoSn, Mn₂FeSb, Mn₂CoAl, Mn₂CoGe, Mn₂CoSi, and Mn₂CuSi and the another one of the first magnetic layer and the second magnetic layer is selected from the group consisting of Fe, Co—Fe, Co—Fe—B, Fe—B and Co—Mn. Technical benefits include fabrication using these readily available compounds.

The tunnel barrier can be selected, for example, from the group consisting of SrO and BaO. Technical benefits include enhanced lattice matching to the magnetic layers.

In some cases, the at least one oxide layer comprises a first oxide layer; the oxide layer lattice constant comprises a first oxide layer lattice constant; and the tunnel barrier further includes a second oxide layer with a second oxide layer lattice constant. Note that the two different oxides do not necessarily match; the bottom magnetic layer could better match the bottom oxide bi-layer and the top magnetic layer could better match the top oxide bi-layer to provide a better-behaved junction. Technical benefits include a better match to the upper and lower magnetic layers as discussed above; with a single layer, the available choices are restricted if it is desired to match at the top and bottom as opposed to a bi-layer where there is a choice available from a larger toolbox of magnetic layers.

In some cases, the first magnetic layer and the second magnetic layer each include a perpendicularly-magnetized Heusler compound, one of which is a free layer and another of which is a fixed layer. Technical benefits include PMA, low moment due to ferrimagnetic configuration, and large magnetic anisotropy.

In some such cases, the first magnetic layer and the second magnetic layer are selected from the group consisting of Mn₃Ge, Mn₃Sn, Mn₃Sb, Mn₂CoSn, Mn₂FeSb, Mn₂CoAl, Mn₂CoGe, Mn₂CoSi, and Mn₂CuSi. Technical benefits include fabrication using these readily available compounds.

In some cases, one of the first magnetic layer and the second magnetic layer includes a perpendicularly-magnetized Heusler compound and another one of the first magnetic layer and the second magnetic layer includes a cubic-based magnetic material. Technical benefits include fabrication using readily available compounds for the layer formation.

In some such cases, the one of the first magnetic layer and the second magnetic layer is selected from the group consisting of Mn₃Ge, Mn₃Sn, Mn₃Sb, Mn₂CoSn, Mn₂FeSb, Mn₂CoAl, Mn₂CoGe, Mn₂CoSi, and Mn₂CuSi and wherein the another one of the first magnetic layer and the second magnetic layer is selected from the group consisting of Fe, Co—Fe, Co—Fe—B, Fe—B and Co—Mn. Technical benefits include fabrication using these readily available compounds.

In some instances, one of the first oxide layer and the second oxide layer is selected from the group consisting of SrO and BaO and another one of the first oxide layer and the second oxide layer is MgO. Technical benefits include fabrication using these readily available compounds and enhanced lattice matching using the SrO and BaO alternatives.

In some such instances, at least one of the first magnetic layer and the second magnetic layer includes a perpendicularly-magnetized Heusler compound; and the one of the first oxide layer and the second oxide layer that is selected from the group consisting of SrO and BaO is in direct contact with the at least one of the first magnetic layer and the second magnetic layer that includes the perpendicularly-magnetized Heusler compound. Technical benefits include enhanced lattice matching.

In another aspect, a magnetoresistive random-access memory array includes: a plurality of bit lines and a plurality of complementary bit lines forming a plurality of bit line-complementary bit line pairs; a plurality of word lines intersecting the plurality of bit line pairs at a plurality of cell locations; and a plurality of magnetoresistive random-access memory cells located at each of the plurality of cell locations. Each of the magnetoresistive random-access memory cells is electrically connected to a corresponding bit line and selectively interconnected to a corresponding one of the complementary bit lines under control of a corresponding one of the word lines. Each of the plurality of magnetoresistive random-access memory cells includes: a first magnetic layer having a first lattice constant; a second magnetic layer having a second lattice constant; and a tunnel barrier between the first and second magnetic layers, where the tunnel barrier includes at least one oxide layer with an oxide layer lattice constant, and where the oxide layer lattice constant has a mismatch smaller than six percent with at least one of the first and second lattice constants. Technical benefits include providing an array with alternate tunnel barrier materials (e.g., as compared to MgO) with better lattice matching to, e.g., tetragonal Heusler compounds to achieve their full potential for use in MRAMs and the like; use of oxides that have a small lattice mismatch with, e.g., tetragonal Heusler compounds which helps to preserve the tetragonal structure of Heusler compounds, which provides large magnetic anisotropy; use of oxides that have a small lattice mismatch with, e.g., tetragonal Heusler compounds which reduces lattice dislocations in Heusler compounds, especially near the interface, leading to better magnetic uniformity and potentially high TMR ratio.

In some cases, each of the plurality of magnetoresistive random-access memory cells further comprises a templating layer, where at least one of the magnetic layers comprises a perpendicularly-magnetized Heusler compound grown on the templating layer, and where the oxide layer lattice constant has the mismatch smaller than six percent with the at least one of the magnetic layers that comprises the perpendicularly-magnetized Heusler compound grown on the templating layer.

Technical benefits include templating layers that facilitate growth of the Heusler material to more closely match the lattice constant of the alternate tunnel barrier.

In some embodiments, the at least one of the magnetic layers that comprises the perpendicularly-magnetized Heusler compound grown on the templating layer comprises a free layer. Technical benefits include PMA, low moment due to ferrimagnetic configuration, and large magnetic anisotropy.

In some instances, the tunnel barrier includes only the at least one oxide layer. Technical benefits include a simple way to fabricate the tunnel barrier.

In some embodiments, the at least one oxide layer comprises a first oxide layer; the oxide layer lattice constant comprises a first oxide layer lattice constant; and the tunnel barrier further includes a second oxide layer with a second oxide layer lattice constant. Technical benefits include enhanced lattice matching.

In some such embodiments, the first magnetic layer and the second magnetic layer each include a perpendicularly-magnetized Heusler compound, one of which is a free layer and another of which is a fixed layer. Technical benefits include PMA, low moment due to ferrimagnetic configuration, and large magnetic anisotropy.

In still another aspect, a method of forming a magnetoresistive random-access memory cell is provided, comprising: providing a substrate; forming a first magnetic layer outward of the substrate, the first magnetic layer having a first lattice constant; forming a tunnel barrier outward of the first magnetic layer, where the tunnel barrier includes at least one oxide layer with an oxide layer lattice constant; and forming a second magnetic layer outward of the tunnel barrier. The second magnetic layer has a second lattice constant. The oxide layer is formed such that the oxide layer lattice constant has a mismatch smaller than six percent with at least one of the first and second lattice constants. Technical benefits include forming cells and or arrays with benefits as described above.

In yet a further aspect, a hardware description language (HDL) design structure is encoded on a machine-readable data storage medium. The HDL design structure includes elements that when processed in a computer-aided design system generate a machine-executable representation of a magnetoresistive random-access memory cell and/or array, as described. Technical benefits include computer-aided formation of cells and or arrays with benefits as described above.

Techniques as disclosed herein can provide substantial beneficial technical effects. Some embodiments may not have these potential advantages and these potential advantages are not necessarily required of all embodiments. By way of example only and without limitation, one or more embodiments may provide one or more of:
alternate tunnel barrier (as compared to MgO) with better lattice matching to tetragonal Heusler compounds to achieve their full potential for use in MRAM;
use of oxides that have a small lattice mismatch with tetragonal Heusler compounds which helps to preserve the tetragonal structure of Heusler compounds, which provides large magnetic anisotropy;
use of oxides that have a small lattice mismatch with tetragonal Heusler compounds which reduces lattice dislocations in Heusler compounds, especially near the interface, leading to better magnetic uniformity and potentially high TMR ratio;
templating layers that facilitate growth of the Heusler material to more closely match the lattice constant of the alternate tunnel barrier.

We have found that tetragonal Heusler compounds, which include Mn₃Z with (in non-limiting examples) Z=Ge, Sn, and Sb, are of interest for MRAM applications, as they exhibit PMA, have low moment due to ferrimagnetic configuration, and exhibit large magnetic anisotropy. The composition can be, for example, Mn_{3.3-x}Z, with x being in the range from 0 to not more than 1.1. Alternatively, the Heusler compound may be a ternary Heusler, e.g., Mn_{3.3-x}Co_{1.1-y}Sn, in which x≤1.2 and y≤1.0. In addition, most of these Heusler compounds has been predicted to have high spin polarization that may lead to high tunneling magnetoresistance (TMR) ratio. In one or more embodiments, the Heusler compound is a perpendicularly-magnetized tetragonal Heusler compound such as (in non-limiting examples) Mn₃Ge, Mn₃Sn, Mn₃Sb, Mn₂CoSn, Mn₂FcSb, Mn₂CoAl, Mn₂CoGe, Mn₂CoSi, and Mn₂CuSi (these compounds are listed with their nominal compositions; however, small variations (typically ≤±10%) from nominal composition of individual components within a Heusler compound should be possible).

In one or more embodiments, the thickness of the Heusler storage layer in an STT-MRAM application is ultrathin (˜ 20 Å). Ternary systems may be a bit harder to grow than binary systems. Half metallicity gives higher TMR (measure of change in resistance as device switches states).

Current MRAM devices use a magnetic tunnel junction (MTJ) as a storage element. A simple MTJ is a tri-layer structure containing two magnetic layers separated by tunnel barrier layer. Current MTJs using Cobalt Iron Boron (Co/Fe/B) are able to provide magnetic layers which have magnetization perpendicular to the film surface (i.e. exhibit perpendicular magnetic anisotropy (PMA), which is desirable). The perpendicular magnetic anisotropy (PMA) of Co—Fe—B layers arises from the interfaces between these layers and the tunnel barrier and/or the underlayer on which the Co—Fe—B layer is deposited.

It is desirable that magnetic materials have volume PMA rather than interfacial PMA, as this enables scaling of devices to smaller sizes (typically smaller diameter). As device size is reduced, the devices become less thermally stable. However, for devices with volume anisotropy, it is advantageously possible to compensate for the lowering of thermal stability by increasing the magnetic layer thickness. The switching current is proportional to the product (Mₛ V Hₖ) where Mₛ is saturation magnetization, V is volume, and Hₖ is the anisotropy field. Low moment (i.e., low Mₛ) Heusler compounds need lower switching currents than high moment materials (such as CoFe alloys) with the same thermal energy barrier, unless the increase in Hₖ overwhelms the lower Mₛ.

Thus, for MRAM applications, it is desirable that all the magnetic elements have their moments perpendicular to the layer itself (i.e., magnetization perpendicular to the film plane—PMA arising from the crystalline structure). Low magnetization and low switching currents are desirable. Additionally, it is desirable that the MTJ devices have bistable switching states, i.e., the entire magnetic volume of the MTJ device switches between its parallel and anti-parallel states in single transitions.

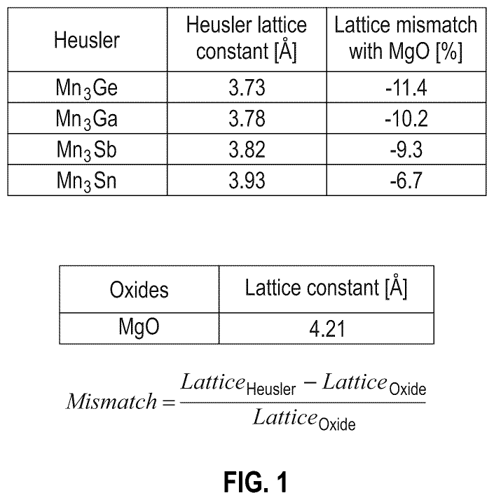

We have found that MTJs utilizing an Mn₃Ge Heusler compound with an MgO tunnel barrier have high TMR (>80%) and fast-switching potential (<10 ns), demonstrating the potential of Heusler compounds for high speed memory applications. Thus, an MgO tunnel barrier along with CoFeB magnetic electrodes can advantageously be used in MTJs, as the TMR achievable is significantly higher than any other tunnel barrier. For example, a TMR>600% can be achieved due to symmetry filtering. However, the TMR for practical application at room temperature with an MgO tunnel barrier with a tetragonal Heusler compound as one of the magnetic electrodes is limited (˜100%). Due to significant lattice mismatch between tetragonal Heusler compounds and the MgO tunnel barrier (see the tables and formula of FIG. 1), the Heusler layer may experience significant tensile strain, which leads to lattice dislocations (a potential cause of magnetic inhomogeneity or non-uniformity) and reduced magnetic anisotropy. In addition, a significant number of lattice dislocations in Heusler compounds interfacing with (or interfaced with) an MgO tunnel barrier may lead to reduced TMR ratio. One or more embodiments advantageously provide an alternate tunnel barrier with better lattice matching to tetragonal Heusler compounds to achieve their full potential for use in MRAM.

Thus, Heusler compounds, such as those shown in FIG. 1, have different lattice constants, and with an MgO tunnel barrier, there is a significant lattice mismatch. The lattice mismatch shown in FIG. 1 is based on theoretical calculations—for an MTJ, the larger the lattice mismatch, the poorer the performance as measured by the TMR. Please note that for brevity, in the equation determining “Mismatch,” the terms Lattice_{Heusler} and Lattice_{Oxide} are respectively employed for the Heusler and Oxide lattice constants.

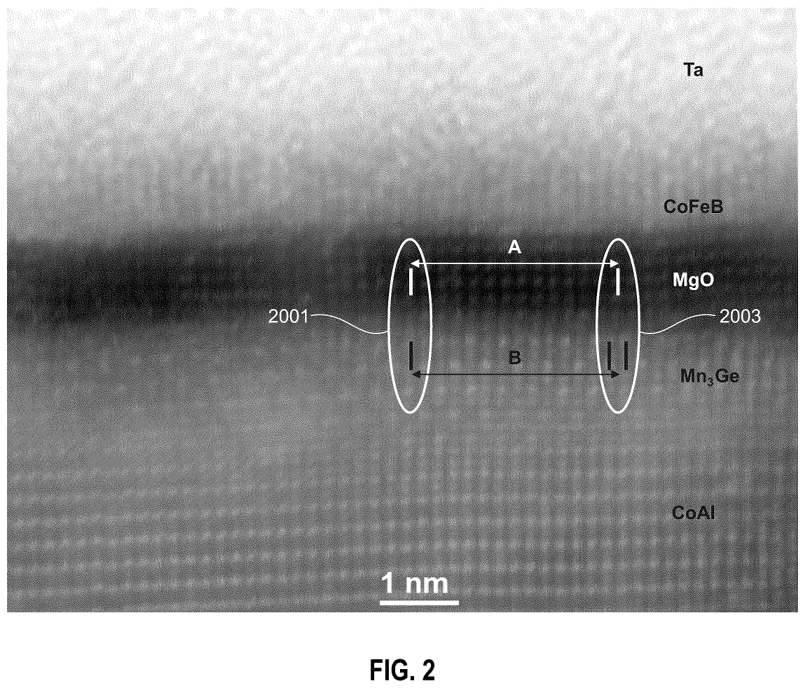

Refer now to FIG. 2, which depicts incoherency at the Mn₃Ge/MgO interface. It can be seen that the MgO tunnel barrier (on top of the Mn₃Ge) maintains its bulk structure/lattice constant (4.21 Angstroms). The MgO grows epitaxially on top of the Mn₃Ge but is not commensurate, and the Mn₃Ge is epitaxial and commensurate to the CoAl, with an in-plane lattice constant of 4.04 Angstroms. However, while on the left side of the image at 2001, all the columns line up (i.e., MgO and Mn₃Ge columns are aligned), moving to the right at 2003, there is a different number of columns because MgO maintains its lattice constant of 4.21 Å; it is not influenced by the underlying Mn₃Ge layer (i.e., MgO and Mn₃Ge column alignment is out of phase). This observation is pertinent to one or more embodiments, in that, to obtain a higher TMR, one or more embodiments provide better lattice matching between the oxide tunnel barrier and the Heusler layer. We have found that it is possible to influence the Mn₃Ge layer in-plane lattice constant by proper choice of the underlying templating layer. Indeed, we have found that there are several good templating layers which permit advantageous adjustment of the in-plane lattice constant. However, even with this technique, the in-plane lattice constant still cannot be adjusted to match it to the MgO. It can be seen in FIG. 2 that the Mn₃Ge in-plane lattice constant is 4.04 Å which is quite different from the native lattice constant of 3.73 Å in the table of FIG. 1. We have found that this change can be achieved by epitaxial growth on top of a chemical templating layer such as CoAl layer. The length of Line A is (4.21/2)*13=27.37 Å while the length of Line B is (4.04/2)*13.5=27.27 Å. The left sides of arrows A and B are aligned and the columns of MgO and Mn₃Ge atoms are coincident. Moving to the right, the columns of atoms in the Mn₃Ge do not line up with the columns of atoms in the MgO anymore; at the right sides of the arrows, the MgO and Mn₃Ge atoms are off by half a spacing. The right side of arrow B is between the two vertical lines which indicate the position of the atoms. A slight drift in the columns of atoms can also be seen at the interface between the MgO and Mn₃Ge.

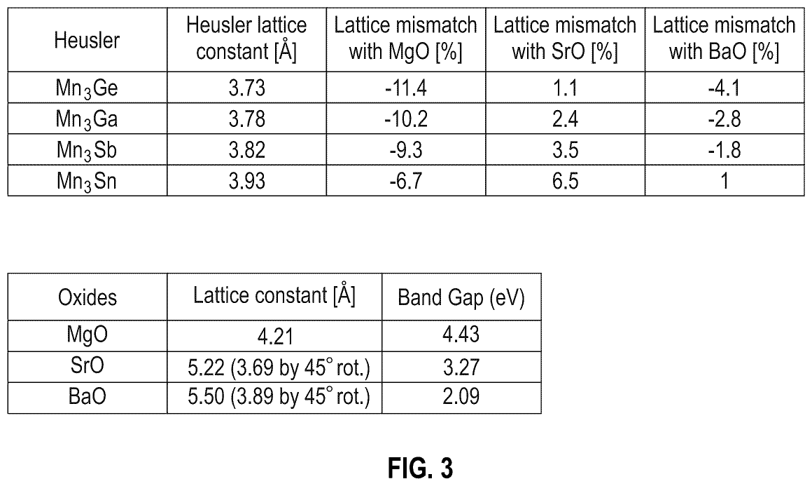

In one or more embodiments, insulating oxides such as SrO and BaO are employed as tunnel barriers since they have a smaller lattice mismatch with tetragonal Heusler compounds; in particular, in comparison to MgO (see tables of FIG. 3). SrO and BaO have a cubic-NaCl structure (similar to MgO) and have a significantly wide band gap, suggesting their potential as a tunnel barrier in MTJ (see tables of FIG. 3). In one or more embodiments, there are two materials, one grown on top of the other. The lattice constants in the top table in FIG. 3 are in-plane lattice constants for the four indicated Heusler materials. Looking at the bottom table in FIG. 3, the significant difference in the lattice constants of the three oxide materials from the Heusler materials can be seen. Regarding the notation “by 45° rot,” if the lattice constant of Mn₃Ge is multiplied by \sqrt{2}, along the diagonal direction, it approaches 5.2 so that the SrO lattice will rotate with respect to the Mn₃Ge by 45° and the position of the atoms in each material can be matched (similar comments apply to BaO). Mg, Sr, and Ba are alkaline earth elements (in the second column of the periodic table of the elements) with an oxidation state of +2. SrO and BaO can be utilized as a single-layer tunnel barrier or bi-layer tunnel barrier in combination with MgO. In the bi-layer tunnel barrier, tetragonal Heusler compounds are directly interfaced with SrO or BaO. Two exemplary particular advantages of using oxides that have a small lattice mismatch with tetragonal Heusler compounds are as follows: (i) helps to preserve the tetragonal structure of Heusler compounds, which provides large magnetic anisotropy; and (ii) reduce lattice dislocations in Heusler compounds, especially near the interface, leading to better magnetic uniformity and potentially high TMR ratio. Moreover, we have found that lattice mismatch can be even further reduced/tuned by combining Heusler compounds with a judiciously chosen chemical templating layer material (typically, an ultrathin Heusler layer grown epitaxially on a chemical templating layer (CTL) and adopting the lattice constant of the Chemical Templating Layer). Refer for example to the TEM image in FIG. 2.

In the tables of FIG. 3, note that the lattice constants of the Heusler compounds are obtained from density functional theory (DFT) calculations. The DFT calculations are generally quite close to empirically determined values (typically within a few percent), but do not necessarily match exactly; for example, according to published sources, it has been empirically determined that D0₂₂ Mn₃Ge has a lattice constant of 3.816 Å to 3.85±0.03 Å. The band gap of the oxides and the NaCl structure are obtained from a public web site that provides computed information on known and predicted materials.

Based on the discussion of FIG. 3, it will be appreciated that one or more embodiments employ a templating layer to tune the lattice constant of the Heusler layer, enhancing the ability to match same with that of alternative tunnel barriers such as SrO and BaO.

Typically, half metallic Heusler compounds tend to be cubic. Thus, a thin film is grown, and the magnetic moment will be in the plane of the layer. For an MTJ for MRAM applications, however, it is highly desirable for the magnetic moments of the magnetic layer to be perpendicular to the layer. One or more embodiments advantageously make half metallic Heusler compounds tetragonal with non-zero anisotropy by using an underlayer with a different in-plane lattice constant (as compared to the cubic form), obtaining volume anisotropy as opposed to interfacial anisotropy. Templating layers that facilitate growth of the Heusler material to more closely match the lattice constant of the alternate tunnel barrier are selected in one or more embodiments. In one or more embodiments, the Heusler material can be the bottom electrode of the MRAM cell. On the other hand, in one or more embodiments, the Heusler compound can be the top electrode of the MRAM cell.

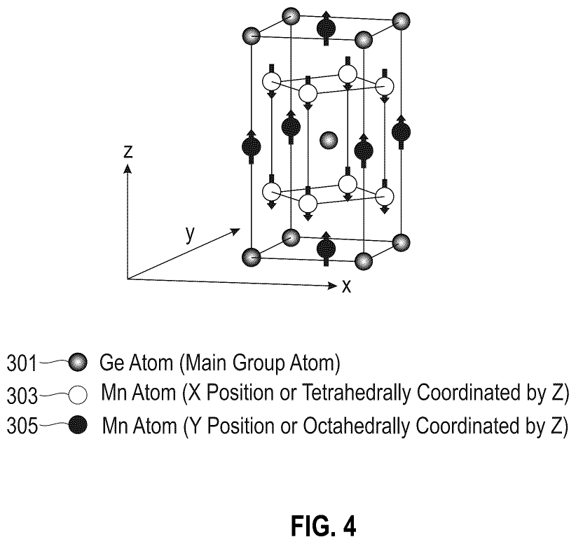

One or more embodiments make use of a templating layer (in a non-limiting example, a chemical templating layer (CTL)). Referring to FIG. 4 consider now aspects of an exemplary chemical templating layer. A Heusler compound such as Mn₃Ge (alternately Mn₃Sn or Mn₃Sb) includes alternating layers of Mn—Mn and Mn—Ge atoms. In FIG. 4, atoms with shading 301 represent Ge atoms (main group), atoms with shading 303 represent Mn atoms of the X-position in X₂YZ (tetrahedrally coordinated by Z), and atoms with shading 305 represent element Mn atoms of the Y-position in X₂YZ (octahedrally coordinated by Z). Mn is a transition metal and Ge is from the main group of the periodic table. One of the alternating layers contains transition metal atoms 303 only and other contains main group element atoms 301 along with transition metal atoms 305. Thus, a seed layer containing a single element which lattice-matches the in-plane lattice constant does not promote growth of an ordered Heusler compound at low temperatures such as room temperature. An ideal seed layer includes a binary compound of a transition element and a main group element. Moreover, this ideal seed layer also has an alternating layer structure containing these two distinct elements. One layer has only the transition metal. The other layer has only the main group element (the “Z” in X₂YZ is a main group element as well). These binary compounds have a CsCl-like (cesium chloride-like) structure (where each cesium ion is coordinated by eight chloride ions). Exemplary templating layers include CoAl, CoGa, others as discussed elsewhere herein, and the like.

Referring to the crystal structure in FIG. 4, all 3 axes are not the same; dimensions a and b (not labelled in the figure, along the x and y axes) are the same in the depicted example, while dimension c (not labelled in the figure, along the vertical z axis) is different. Note the magnetization arrows going up and down along z. Stretching of crystals in the z direction yields volume anisotropy. Note the alternating layer structure. Use of a seed layer with alternating layer structure containing two distinct elements (one transition metal and other main group element) allows for chemical ordering even during room-temperature growth.

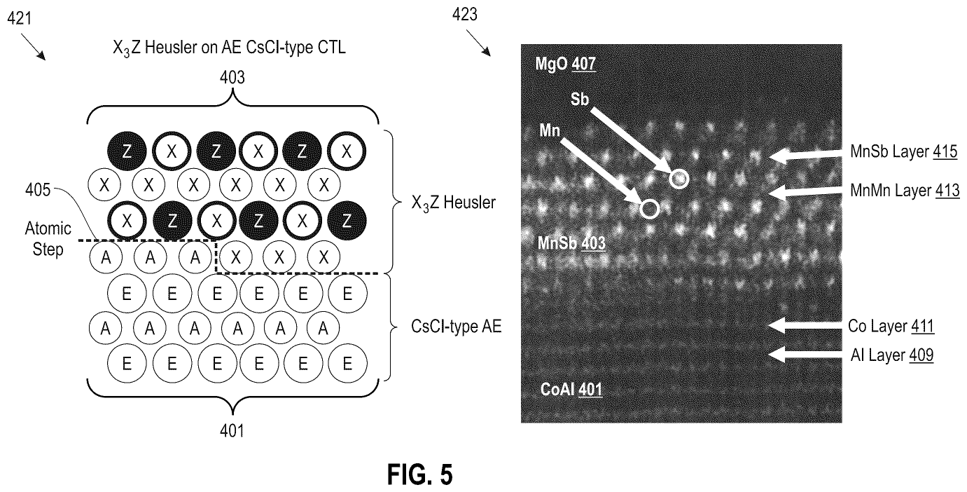

Referring now to FIG. 5, one or more embodiments employ a CsCl-type chemical templating layer (CTL) 401 (CoAl is an example of an excellent CsCl-type CTL) which promotes growth of an ordered Heusler compound even at ultrathin thicknesses and at room temperature. “E” can correspond, for example, to Al and “A” can correspond, for example, to Co. In FIG. 5, view 421 is a schematic while view 423 is a transmission electron microscopy (TEM) image. A Heusler compound such as Mn₃Ge or Mn₃Sn or Mn₃Sb 403 grows epitaxially on top of the CoAl layer 401. In one or more embodiments, the in-plane lattice constant of the ultrathin (<˜ 25 Å) Heusler compound is similar to that of the CoAl CTL layer. It is possible to strain the Heusler layer to a differing extent with appropriate choice of the CTL layer. We have found that even ternary Heusler compounds can be ordered by the CTL. Note that one or more embodiments use alternative templating layers so that the lattice constant of the Heusler layer more closely matches that of the alternative oxide tunnel barrier.

In the example of FIG. 5, the in-plane lattice constant of the ultrathin Heusler compound is similar to that of the CoAl CTL. It is possible to strain the Heusler to a differing extent with an appropriate choice of CTL. We have found that even ternary Heusler compounds can be ordered by the CTL. As illustrated, the Mn (generally, X) grows on the Al and the Sb (generally, Z) grows on the Co. Note the atomic step 405. The Heusler material can be strained and thus adopts the in-plane lattice constant of the template material. One or more embodiments impose the lattice constant of the templating layer onto the Heusler layer. In view 423, note that CoAl 401 includes Al layers 409 and Co layers 411 and the Mn₃Sb 403 includes MnMn layer 413 and MnSb layer 415. Note the MgO tunnel barrier 407. The three most prominent tetragonal compounds are Mn₃Ge, Mn₃Sn, and Mn₃Sb, and Mn₃Sb has a larger difference in atomic number between Mn and Sb and thus is easier to see in the TEM image 423.

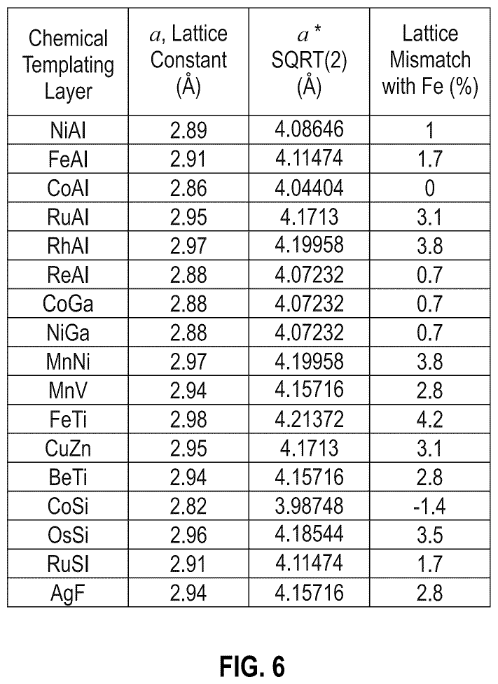

FIG. 6 shows potential chemical templating layer (CTL) candidates (first column) for the bottom free layer; the CTL materials in FIG. 6 have a CsCl structure (alternating layer structure). The second column shows the lattice constant, a, for the CTL candidates; the third column shows a\sqrt{2}, and the fourth column shows the lattice mismatch with iron as a percentage. The parameter a, the in-plane lattice constant of the Heusler layer, can be tuned over a large range of values by choice of CTL. These “a” values can also be adjusted further with strain induced from an underlying seed layer and/or a change in composition from the nominal 1:1 value. The use of a chemical templating layer and Heusler compound combination will allow even better lattice matching with the oxide tunnel barrier.

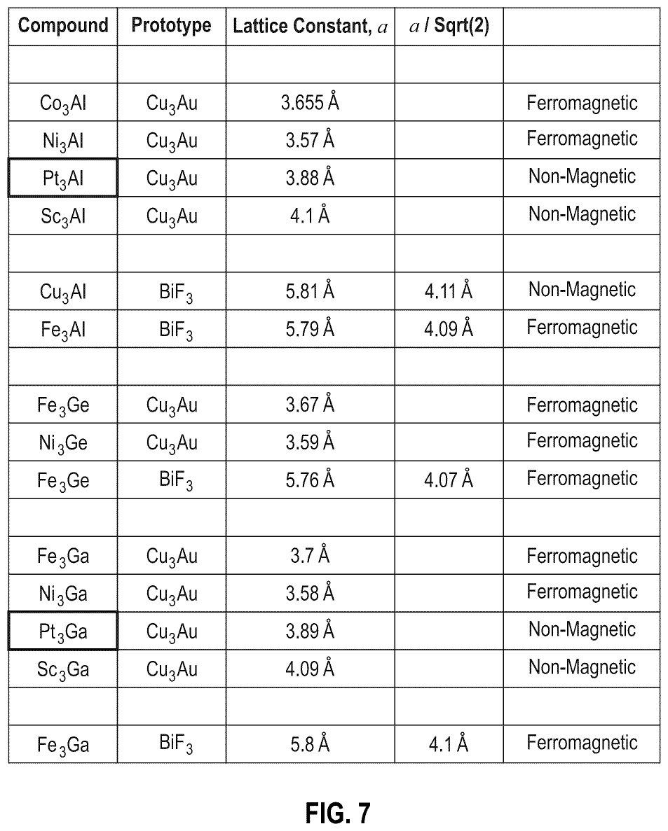

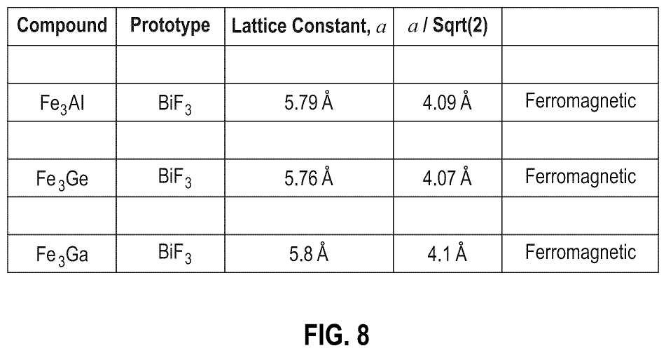

FIG. 7 shows potential chemical templating layer (CTL) candidates (first column) for the bottom free layer; the CTL materials in FIG. 7 have a Cu₃Au structure. The second column shows the prototype (the prototype is a well-known concept in inorganic chemistry, where a large number of compounds often crystallize with very similar atom arrangements—the prototype is referred to in the tables of FIGS. 7 and 8 by the name of a well-known compound with the same kind of atom arrangement). The third column shows the lattice constant, a, and the fourth column shows a/\sqrt{2}. The final column indicates whether the compound is ferromagnetic or non-magnetic. Note that the lattice constant of CoAl is 4.04 Å, and that Pt₃Al and Pt₃Ga will also provide a Spin Hall contribution to act as a Spin Orbit Torque (SOT) generator. One or more embodiments enable 3T (three-terminal) or even 2T (two-terminal) SOT-MRAM devices.

FIG. 8 shows proposed Fe₃X magnetic compounds as candidates (first column) for the top CTL; the CTL materials in FIG. 8 have a BiF₃ structure. The second column shows the prototype. The third column shows the lattice constant, a, and the fourth column shows a/\sqrt{2}. The final column indicates that all the compounds in FIG. 8 are ferromagnetic. The lattice constant of the MgO tunnel barrier is 4.20 Å and the lattice mismatch of these materials to the MgO tunnel barrier is ˜2 to 3%. These structures are layered compounds similar to the CsCl structure discussed elsewhere herein. One layer has only the transition metal element, Fe, while the other layer has a main group element plus the transition metal element, i.e., Fe—X. The layered structures are de-facto similar to the Heusler D0₂₂ Mn₃Ge structure which has alternating layers of Mn—Mn and Mn—Ge as seen in FIG. 4.

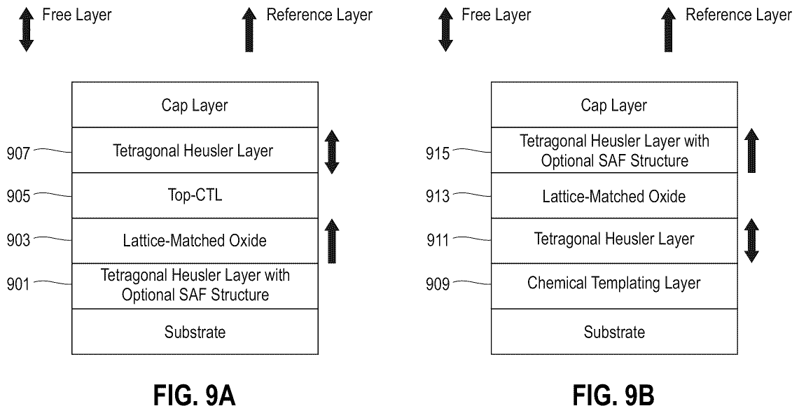

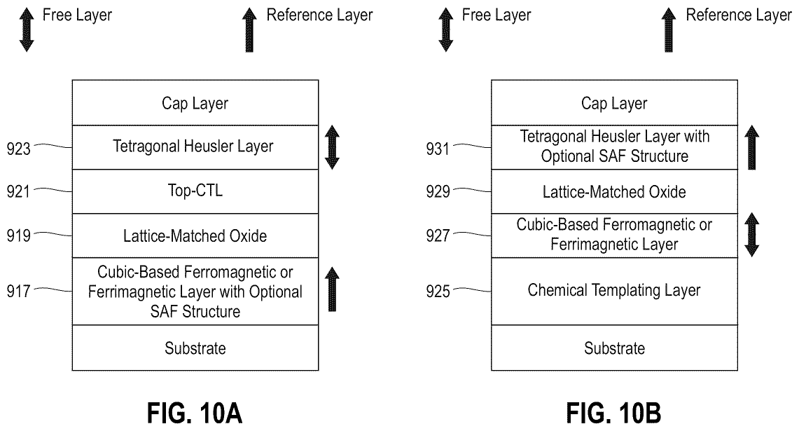

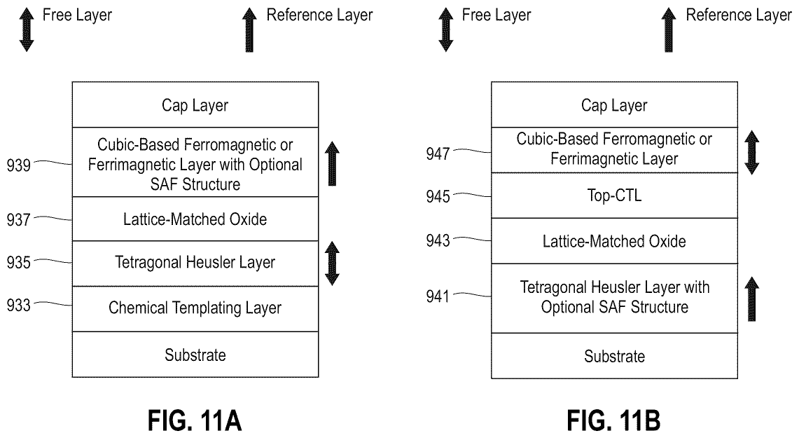

Refer now to FIGS. 9A-11B. In each case, the free layer is indicated by a double-headed arrow and the reference layer by a single-headed arrow. The embodiment of FIG. 9A includes a tetragonal Heusler layer 901, optionally with a synthetic anti-ferromagnet (SAF) structure. Also included are lattice-matched oxide 903, top-CTL 905, and tetragonal Heusler layer 907. The embodiment of FIG. 9B includes CTL 909, tetragonal Heusler layer 911, lattice-matched oxide 913, and tetragonal Heusler layer 915, optionally with an SAF structure. The embodiment of FIG. 10A includes a cubic-based ferromagnetic or ferrimagnetic layer 917, optionally with a synthetic anti-ferromagnet (SAF) structure. Also included are lattice-matched oxide 919, top-CTL 921, and tetragonal Heusler layer 923. The embodiment of FIG. 10B includes CTL 925, cubic-based ferromagnetic or ferrimagnetic layer 927, lattice-matched oxide 929, and tetragonal Heusler layer 931, optionally with an SAF structure. The embodiment of FIG. 11A includes a CTL 933, a tetragonal Heusler layer 935, a lattice-matched oxide 937, and a cubic-based ferromagnetic or ferrimagnetic layer 939, optionally with a synthetic anti-ferromagnet (SAF) structure. The embodiment of FIG. 11B includes a tetragonal Heusler layer 941, optionally with a synthetic anti-ferromagnet (SAF) structure. Also included are lattice-matched oxide 943, top-CTL 945, and a cubic-based ferromagnetic or ferrimagnetic layer 947.

The examples in each of FIGS. 9A-11B can include a substrate at the bottom and a cap layer at the top, not separately numbered, with optional intervening layers as will be apparent to the skilled artisan.

FIG. 8 is a table showing three exemplary compounds for the top CTL, each having the prototype atom arrangement of BiF₃, and showing the lattice constant, a, and the value of a/\sqrt{2}. Each compound is ferromagnetic and is referred to generically as Fe₃X. The lattice constant of an exemplary MgO tunnel barrier is 4.20 Å, and the lattice mismatch of these materials to the exemplary MgO tunnel barrier is ˜2 to 3%. These structures are layered compounds similar to the CsCl structure discussed elsewhere herein. One layer has only the transition metal element, Fe, while the other layer has a main group element plus a transition metal element, Fe—X. The layered structures are de-facto similar to the Heusler D0₂₂ Mn₃Ge structure which has alternating layers of Mn—Mn and Mn-Gc.

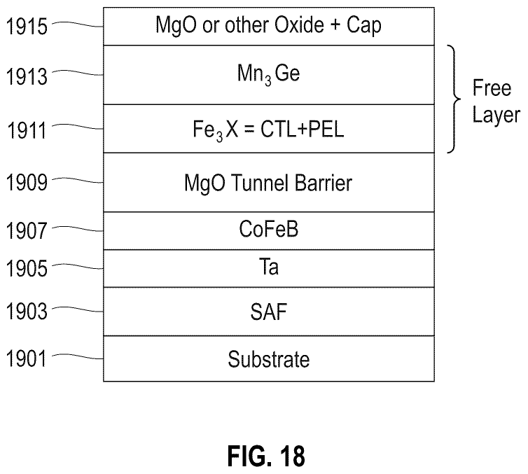

Referring to FIG. 18, consider further aspects of use of Fe₃X as a top-chemical templating layer (T-CTL). Fe₃X are ferromagnetic alloys, where X=Al, Ga, or Ge. The lattice constant of these alloys is ˜4.1 Å and hence they are likely to grow on top of an MgO tunnel barrier whose lattice constant is 4.20 Å. The exemplary structure in FIG. 18 includes substrate 1901, SAF 1903, Ta layer 1905, CoFeB layer 1907, MgO tunnel barrier 1909, Fe₃X layer 1911, Mn₃Ge layer 1913, and a layer 1915 including MgO or other oxide plus a top cap. Layers 1911, 1913 form the free layer in this example. In some instances, growth of an ultrathin Fe₃X layer involves deposition at a cryocooled temperature to avoid wetting issues. Fe₃X advantageously promotes growth of a PMA Heusler compound. In one or more embodiments, the ultrathin Fe₃X will function as the polarization enhancement layer (PEL) due to the high spin polarization (in the example, the Fe₃X layer 1911 encompasses a CTL and PEL). This aspect thus provides the top free layer implementation of a Heusler compound with advantages such as: enabling use of a highly optimized bottom SAF reference layer; ability to deposit additional MgO on top of the Mn₃Ge layer to minimize spin pumping; and/or lower switching current. As will be appreciated by the skilled artisan, given the teachings herein, there can be additional layers interposed between Substrate 1901 and SAF 1903.

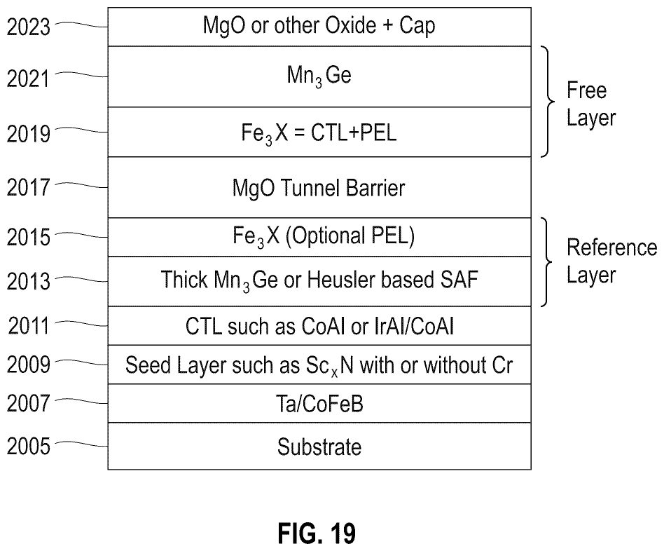

Referring to FIG. 19, in some instances, Fe₃X as a top CTL enables a Heusler compound based STT switchable MTJ. The exemplary structure in FIG. 19 includes substrate 2005, Ta/CoFeB layer 2007, and a seed layer 2009 such as ScₓN with or without Cr. Also included are a CTL 2011 such as CoAl or IrAl/CoAl, and a thick Mn₃Ge or Heusler based SAF layer 2013, an Fe₃X layer 2015 optionally encompassing PEL, MgO tunnel barrier 2017, Fe₃X layer 2019, Mn₃Ge layer 2021, and a layer 2023 including MgO or other oxide plus a top cap. Layers 2019, 2021 form the free layer in this example and layers 2013, 2015 form the reference layer. In the example, the Fe₃X layer 2019 encompasses a CTL and PEL.

In some cases, the Heusler layer underneath the tunnel barrier is the reference layer. The Heusler layer thickness can be chosen, e.g., such that its coercivity, He, can be >10 kOe. For Mn₃Ge, this thickness can be >30 Å. For the reference layer Heusler compound, it is possible to use the stack developed with seed layers such as ScₓN, Cr, bi-layer of IrAl/CoAl, and the like. Optionally, Fe₃X can be used as a polarization enhancement layer above a bottom Heusler reference layer. Fe₃X should have a high spin polarization. In the top free layer implementation of a Heusler compound, Fe₃X/MgO/Fe₃X can have symmetry spin filtering and thus have significantly enhanced TMR.

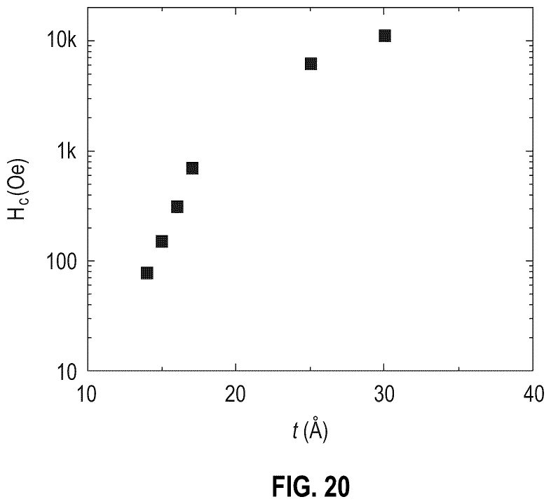

FIG. 20 shows the dependence of coercivity H_{c} in Oersteds (Oc) on Heusler layer thickness, t, in Angstroms for an example stack including:

Si/250 SiO₂/50Ta/30Ru/20Ta/5CoFeB₂₀/300MnN(85:15)/650CoAl_IBD/‘t’ Mn_{2.6}Ge (annealed at ˜340° C.)/17MgO/20Ta.

Referring again to FIGS. 9A-11B, one or more embodiments provide a structure including a first magnetic layer; a second magnetic layer; and a tunnel barrier between the first and second magnetic layers. The tunnel barrier is made of a single oxide layer that has lattice mismatch smaller than 6% with at least one of the magnetic layers. In some instances, both magnetic layers are chosen from perpendicularly-magnetized tetragonal Heusler compounds such as (non-limiting examples) Mn₃Ge, Mn₃Sn, Mn₃Sb, Mn₂CoSn, Mn₂FeSb, Mn₂CoAl, Mn₂CoGe, Mn₂CoSi, and Mn₂CuSi. In some cases, one of the magnetic layers is chosen from perpendicularly-magnetized tetragonal Heusler compounds such as Mn₃Ge, Mn₃Sn, Mn₃Sb, Mn₂CoSn, Mn₂FeSb, Mn₂CoAl, Mn₂CoGe, Mn₂CoSi, and Mn₂CuSi, while the other magnetic layer is chosen from cubic-based ferromagnetic or ferrimagnetic materials such as Fe, Co—Fe, Co—Fe—B, Fe—B and Co—Mn. In one or more embodiments, the tunnel barrier is either SrO or BaO.

Thus, generally, it is worth noting that one or more embodiments include an underlying template layer which has its own lattice constant that can be changed based on the choice of material. The underlying template layer can be used to tune the lattice constant of the Heusler layer to better match the oxide layer.

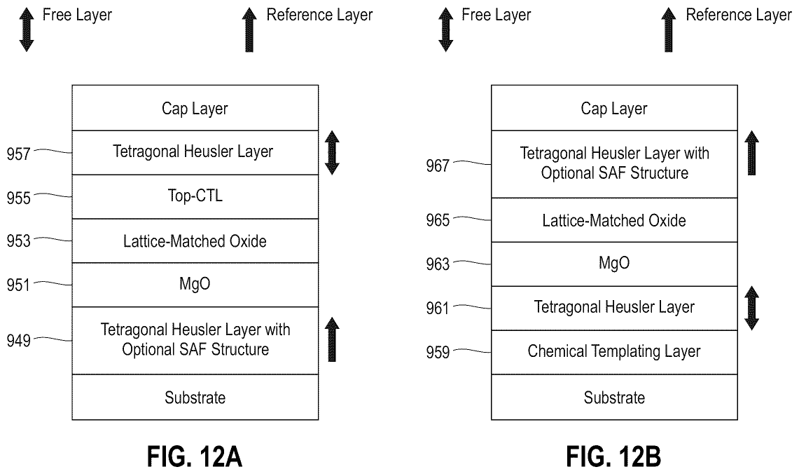

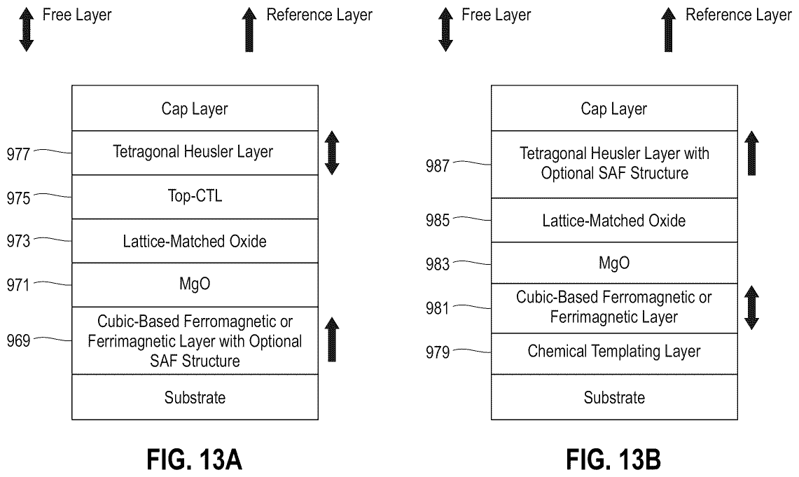

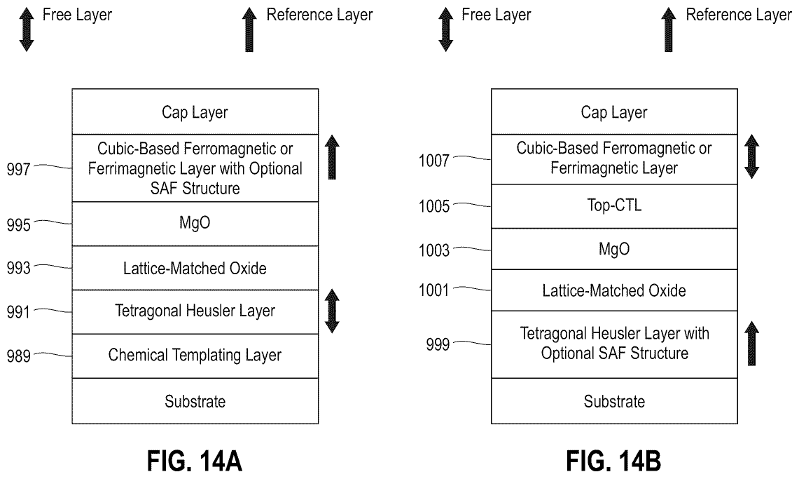

Refer now to FIGS. 12A-14B. In each case, the free layer is indicated by a double-headed arrow and the reference layer by a single-headed arrow. The embodiment of FIG. 12A includes a tetragonal Heusler layer 949, optionally with a synthetic anti-ferromagnet (SAF) structure. Also included are MgO 951, lattice-matched oxide 953, top-CTL 955, and tetragonal Heusler layer 957. The embodiment of FIG. 12B includes CTL 959, tetragonal Heusler layer 961, MgO 963, lattice-matched oxide 965, and tetragonal Heusler layer 967, optionally with an SAF structure. The embodiment of FIG. 13A includes a cubic-based ferromagnetic or ferrimagnetic layer 969, optionally with a synthetic anti-ferromagnet (SAF) structure. Also included are MgO 971, lattice-matched oxide 973, top-CTL 975, and tetragonal Heusler layer 977. The embodiment of FIG. 13B includes CTL 979, cubic-based ferromagnetic or ferrimagnetic layer 981, MgO 983, lattice-matched oxide 985, and tetragonal Heusler layer 987, optionally with an SAF structure. The embodiment of FIG. 14A includes a CTL 989, a tetragonal Heusler layer 991, a lattice-matched oxide 993, MgO 995, and a cubic-based ferromagnetic or ferrimagnetic layer 997, optionally with a synthetic anti-ferromagnet (SAF) structure. The embodiment of FIG. 14B includes a tetragonal Heusler layer 999, optionally with a synthetic anti-ferromagnet (SAF) structure. Also included are lattice-matched oxide 1001, MgO 1003, top-CTL 1005, and a cubic-based ferromagnetic or ferrimagnetic layer 1007.

Thus, still referring to FIGS. 12A-14B, one or more embodiments provide a structure including a first magnetic layer; a second magnetic layer; and a tunnel barrier between the first and second magnetic layer. The tunnel barrier is made of two different oxide layers. One of the oxide layers has a lattice mismatch smaller than 6% with at least one of the magnetic layers. In some cases, both magnetic layers are chosen from perpendicularly-magnetized tetragonal Heusler compounds such as (non-limiting examples) Mn₃Ge, Mn₃Sn, Mn₃Sb, Mn₂CoSn, Mn₂FeSb, Mn₂CoAl, Mn₂CoGe, Mn₂CoSi, and Mn₂CuSi. In some instances, one of the magnetic layers is chosen from perpendicularly-magnetized tetragonal Heusler compounds such as (non-limiting examples) Mn₃Ge, Mn₃Sn, Mn₃Sb, Mn₂CoSn, Mn₂FeSb, Mn₂CoAl, Mn₂CoGe, Mn₂CoSi, and Mn₂CuSi, while the other magnetic layer is chosen from cubic-based ferromagnetic or ferrimagnetic materials such as Fe, Co—Fe, Co—Fe—B, Fe—B and Co—Mn.

The examples in each of FIGS. 12A-14B can include a substrate at the bottom and a cap layer at the top, not separately numbered, with optional intervening layers as will be apparent to the skilled artisan.

In some embodiments, one of the oxide layers is made of MgO, and the other oxide layer is either SrO or BaO. In some such embodiments, the oxide layer made of either SrO or BaO is always in direct contact with the magnetic layer made of perpendicularly magnetized tetragonal Heusler compounds.

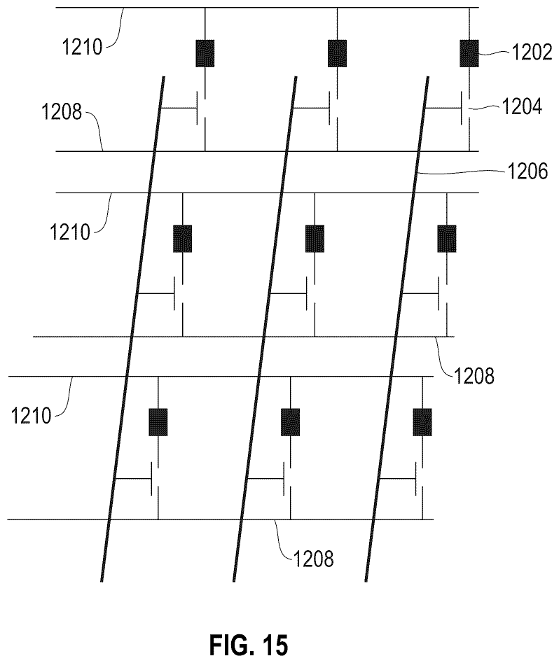

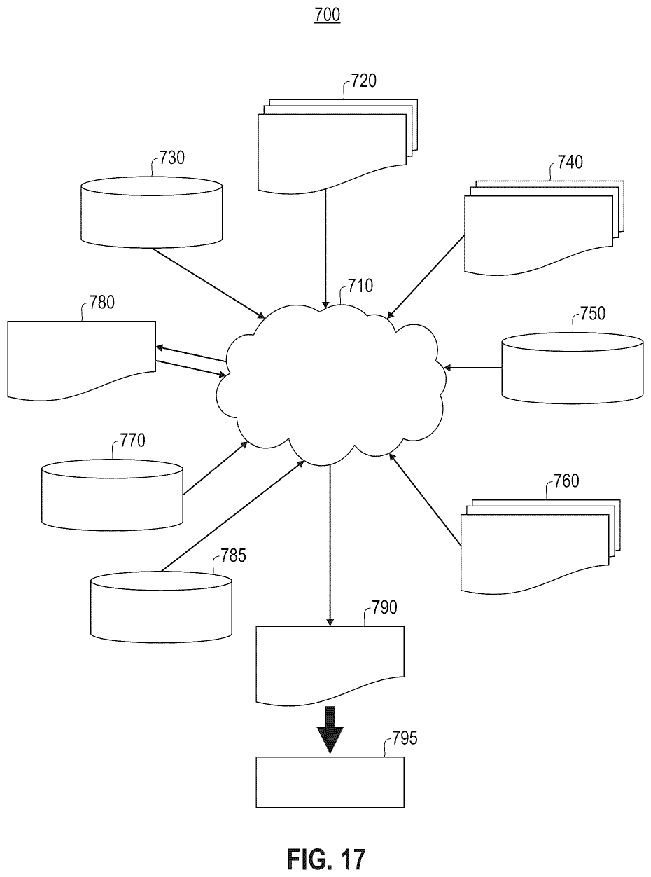

In FIGS. 9A-14B, the substrate can be silicon with CMOS circuitry such as transistors and access lines permitting selection of individual devices. Other than the novel cells described herein, conventional transistors, access lines, peripheral circuits, and the like can be employed-refer to discussion of FIGS. 15 and 17 below. Heusler layers can be formed, for example, by epitaxial growth on the CTL. Various intervening layers could include a polarization enhancement layer (e.g., a thin layer of magnetic material such as cobalt); a synthetic anti-ferromagnet (SAF) layer; and so on. Typically a Synthetic Anti-Ferromagnet (SAF) layer includes a Co/Pt multilayer that is magnetically coupled to the underlying magnetic layer to achieve needed performance. A thin layer (not shown) of Ta or Ir or Ru (order of few Å) may typically be interposed between the magnetic layer and the SAF layer. The cap layer may include Mo, W, Ta, Pt, Ru, or a combination thereof.

In one or more embodiments, the chemical templating layer (CTL), which is the binary alloy with CsCl, structure is represented by A₁₋ₓEₓ, where A is a transition metal element and E is a main group element. For example, A includes Co and E includes at least aluminum or gallium and possibly traces of other elements (e.g., Al or Ga; or Al alloyed with Ga, Ge, Sn, or any combination thereof, such as AlSn, AlGe, AlGaGe, AlGaSn, AlGeSn, and AlGaGeSn), and x is in the range from 0.42 to 0.55. Note also two other exemplary types of CTLs having Cu₃Au and BiF₃ structures which are also alternating layered structures although the composition is different.

By way of review, the Heusler layer can be produced via growth on a suitable templating layer. In a templating concept a templating layer is grown and another layer (e.g., Heusler compound) is grown on top of it. Templating essentially means that the layer being grown on the templating layer grows to the lattice constant a of the underlayer/seed layer.

As will be appreciated by the skilled artisan, typically, the magnetization is not fixed, but rather, the magnetization precesses like a spinning top at a non-zero temperature. This can change depending on temperature. In view of this precession, perpendicularity, as used herein, refers to perpendicularity of the time integral/average of the path of the magnetization. The time integral/average of the path of the magnetization could be, for example, “exactly” perpendicular, perpendicular within ±5%, or perpendicular within ±10%.

It should be noted that the Heusler compounds are indicated by stoichiometric formulas and this does not preclude small variations of up to several % from the nominal values.

Referring now to FIG. 15, an array of MRAM devices 1202 is shown. Each cell 1202 (e.g., embodiment of FIGS. 9A-14B) is connected to a respective transistor 1204 that controls reading and writing. A word line 1206 provides data to write to the cells 1202, while a bit line 1210 and a bit line complement 1208 read data from the cell 1202. In this manner, a large array of memory devices can be implemented on a single chip. An arbitrarily large number of cells 1202 can be employed, within the limits of the manufacturing processes and design specifications.

Writing data to a cell 1202 includes passing a current through the cell. This current causes the direction of magnetization to switch between a parallel or anti-parallel state, which has the effect of switching between low resistance and high resistance. Because this effect can be used to represent the 1s and 0s of digital information, the cells 1202 can be used as a non-volatile memory. Passing the current in one direction through the cell 1202 causes the magnetization of the free layer 1205 to be parallel with that of the reference layer 1211, while passing the current in the other direction through the cell 1202 causes the magnetization of the free layer 1205 to be antiparallel to that of the reference layer 1211. Reading the bit stored in a cell 1202 involves applying a voltage (lower than that used for writing information) to the cell 1202 to discover whether the cell offers high resistance to current (“1”) or low resistance (“0”).

Semiconductor device manufacturing includes various steps of device patterning processes. For example, the manufacturing of a semiconductor chip may start with, for example, a plurality of CAD (computer aided design) generated device patterns, which is then followed by effort to replicate these device patterns in a substrate. The replication process may involve the use of various exposing techniques and a variety of subtractive (etching) and/or additive (deposition) material processing procedures. For example, in a photolithographic process, a layer of photo-resist material may first be applied on top of a substrate, and then be exposed selectively according to a pre-determined device pattern or patterns. Portions of the photo-resist that are exposed to light or other ionizing radiation (e.g., ultraviolet, electron beams, X-rays, etc.) may experience some changes in their solubility to certain solutions. The photo-resist may then be developed in a developer solution, thereby removing the non-irradiated (in a negative resist) or irradiated (in a positive resist) portions of the resist layer, to create a photo-resist pattern or photo-mask. The photo-resist pattern or photo-mask may subsequently be copied or transferred to the substrate underneath the photo-resist pattern.

There are numerous techniques used by those skilled in the art to remove material at various stages of creating a semiconductor structure. As used herein, these processes are referred to generically as “etching”. For example, etching includes techniques of wet etching, dry etching, chemical oxide removal (COR) etching, ion milling, and reactive ion etching (RIE), which are all known techniques to remove select material(s) when forming a semiconductor structure. The Standard Clean 1 (SC1) contains a strong base, typically ammonium hydroxide, and hydrogen peroxide. The SC2 contains a strong acid such as hydrochloric acid and hydrogen peroxide. The techniques and application of etching is well understood by those skilled in the art and, as such, a more detailed description of such processes is not presented herein.

Although the overall fabrication method, including the epitaxial growth of the Heusler material(s), and the structures formed thereby, are novel, certain individual processing steps required to implement the method may utilize conventional semiconductor fabrication techniques and conventional semiconductor fabrication tooling. These techniques and tooling will already be familiar to one having ordinary skill in the relevant arts given the teachings herein. Moreover, one or more of the processing steps and tooling used to fabricate semiconductor devices are also described in a number of readily available publications, including, for example: James D. Plummer et al., Silicon VLSI Technology: Fundamentals, Practice, and Modeling 1^{st} Edition, Prentice Hall, 2001 and P. H. Holloway et al., Handbook of Compound Semiconductors: Growth, Processing, Characterization, and Devices, Cambridge University Press, 2008, which are both hereby incorporated by reference herein. It is emphasized that while some individual processing steps are set forth herein, those steps are merely illustrative, and one skilled in the art may be familiar with several equally suitable alternatives that would be applicable.

It is to be appreciated that the various layers and/or regions shown in the accompanying figures may not be drawn to scale. Furthermore, one or more semiconductor layers of a type commonly used in such integrated circuit devices may not be explicitly shown in a given figure for case of explanation. This does not imply that the semiconductor layer(s) not explicitly shown are omitted in the actual integrated circuit device.

In another aspect, referring to FIG. 15, a magnetoresistive random-access memory array includes a plurality of bit lines 1210 and a plurality of complementary bit lines 1208 forming a plurality of bit line-complementary bit line pairs. A plurality of word lines 1206 intersect the plurality of bit line pairs at a plurality of cell locations. A plurality of magnetoresistive random-access memory cells 1202 are located at each of the plurality of cell locations. Each of the magnetoresistive random-access memory cells 1202 is electrically connected to a corresponding bit line 1210 and selectively interconnected to a corresponding one of the complementary bit lines 1208 under control of a corresponding one of the word lines 1206 (e.g., a respective transistor 1204 is a field effect transistor turned off or on by a signal from word line 1206 applied to its gate, which controls reading and writing and whether the cell is coupled to the complementary bit lines).

Each of the plurality of magnetoresistive random-access memory cells includes a cell as described elsewhere herein with respect to FIGS. 9A-14B. The cells are connected between the bit lines 1210 and the access FETs 1204. Typically, the capping (“cap”) layer of the devices indicated in FIGS. 9A-14B connect to the bit line 1210.

In still another aspect, an exemplary method of operation includes providing an array such as just described, applying signals to the word lines 1206 to cause a first subset of the cells 1202 to store logical ones and a second subset of the cells 1202 to store logical zeroes; and reading the stored logical ones and zeroes via the bit lines 1210 and the complementary bit lines 1208.

In yet another aspect, an exemplary method of forming a magnetoresistive random-access memory cell (such as in FIGS. 9A-14B) includes providing a substrate; forming a first magnetic layer outward of the substrate, the first magnetic layer having a first lattice constant; forming a tunnel barrier outward of the first magnetic layer, where the tunnel barrier includes at least one oxide layer with an oxide layer lattice constant; and forming a second magnetic layer outward of the tunnel barrier. The second magnetic layer has a second lattice constant. The oxide layer is formed such that the oxide layer lattice constant has a mismatch smaller than six percent with at least one of the first and second lattice constants. Technical benefits include forming cells and or arrays with benefits as described above. The method can also include providing and/or forming other elements as discussed, using techniques apparent to the skilled artisan, given the teachings herein. The cells can be integrated into an array by forming a plurality of cells at the same time and interconnecting them with wires, transistors, and peripheral circuitry in a manner apparent to the skilled artisan, given the teachings herein.

Those skilled in the art will appreciate that the exemplary structures discussed above can be distributed in raw form (i.e., a single wafer having multiple unpackaged chips), as bare dies, in packaged form, or incorporated as parts of intermediate products or end products that benefit from a material stack with improved device performance in perpendicularly magnetized Heusler films and the like.

An integrated circuit in accordance with aspects of the present inventions can be employed in essentially any application and/or electronic system where a material stack with improved device performance in perpendicularly magnetized Heusler films and the like would be beneficial. Given the teachings of the present disclosure provided herein, one of ordinary skill in the art will be able to contemplate other implementations and applications of embodiments disclosed herein.

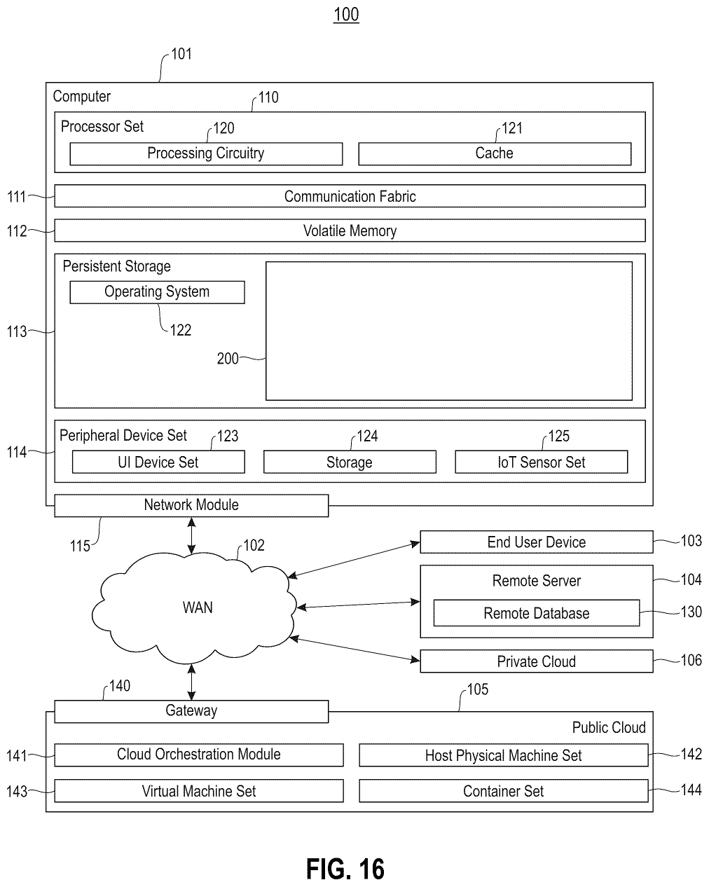

Reference should now be had to FIG. 16, which depicts a computing environment according to an embodiment of the present invention (e.g., for implementing a design process such as that of FIG. 17)

Various aspects of the present disclosure are described by narrative text, flowcharts, block diagrams of computer systems and/or block diagrams of the machine logic included in computer program product (CPP) embodiments. With respect to any flowcharts, depending upon the technology involved, the operations can be performed in a different order than what is shown in a given flowchart. For example, again depending upon the technology involved, two operations shown in successive flowchart blocks may be performed in reverse order, as a single integrated step, concurrently, or in a manner at least partially overlapping in time.

A computer program product embodiment (“CPP embodiment” or “CPP”) is a term used in the present disclosure to describe any set of one, or more, storage media (also called “mediums”) collectively included in a set of one, or more, storage devices that collectively include machine readable code corresponding to instructions and/or data for performing computer operations specified in a given CPP claim. A “storage device” is any tangible device that can retain and store instructions for use by a computer processor. Without limitation, the computer readable storage medium may be an electronic storage medium, a magnetic storage medium, an optical storage medium, an electromagnetic storage medium, a semiconductor storage medium, a mechanical storage medium, or any suitable combination of the foregoing. Some known types of storage devices that include these mediums include: diskette, hard disk, random access memory (RAM), read-only memory (ROM), erasable programmable read-only memory (EPROM or Flash memory), static random access memory (SRAM), compact disc read-only memory (CD-ROM), digital versatile disk (DVD), memory stick, floppy disk, mechanically encoded device (such as punch cards or pits/lands formed in a major surface of a disc) or any suitable combination of the foregoing. A computer readable storage medium, as that term is used in the present disclosure, is not to be construed as storage in the form of transitory signals per se, such as radio waves or other freely propagating electromagnetic waves, electromagnetic waves propagating through a waveguide, light pulses passing through a fiber optic cable, electrical signals communicated through a wire, and/or other transmission media. As will be understood by those of skill in the art, data is typically moved at some occasional points in time during normal operations of a storage device, such as during access, de-fragmentation or garbage collection, but this does not render the storage device as transitory because the data is not transitory while it is stored.

Computing environment 100 contains an example of an environment for the execution of at least some of the computer code involved in performing the inventive methods, such as a system 200 for semiconductor design and/or control of semiconductor fabrication (see FIG. 17). In addition to block 200, computing environment 100 includes, for example, computer 101, wide area network (WAN) 102, end user device (EUD) 103, remote server 104, public cloud 105, and private cloud 106. In this embodiment, computer 101 includes processor set 110 (including processing circuitry 120 and cache 121), communication fabric 111, volatile memory 112, persistent storage 113 (including operating system 122 and block 200, as identified above), peripheral device set 114 (including user interface (UI) device set 123, storage 124, and Internet of Things (IoT) sensor set 125), and network module 115. Remote server 104 includes remote database 130. Public cloud 105 includes gateway 140, cloud orchestration module 141, host physical machine set 142, virtual machine set 143, and container set 144.

COMPUTER 101 may take the form of a desktop computer, laptop computer, tablet computer, smart phone, smart watch or other wearable computer, mainframe computer, quantum computer or any other form of computer or mobile device now known or to be developed in the future that is capable of running a program, accessing a network or querying a database, such as remote database 130. As is well understood in the art of computer technology, and depending upon the technology, performance of a computer-implemented method may be distributed among multiple computers and/or between multiple locations. On the other hand, in this presentation of computing environment 100, detailed discussion is focused on a single computer, specifically computer 101, to keep the presentation as simple as possible. Computer 101 may be located in a cloud, even though it is not shown in a cloud in FIG. 16. On the other hand, computer 101 is not required to be in a cloud except to any extent as may be affirmatively indicated.

PROCESSOR SET 110 includes one, or more, computer processors of any type now known or to be developed in the future. Processing circuitry 120 may be distributed over multiple packages, for example, multiple, coordinated integrated circuit chips. Processing circuitry 120 may implement multiple processor threads and/or multiple processor cores. Cache 121 is memory that is located in the processor chip package(s) and is typically used for data or code that should be available for rapid access by the threads or cores running on processor set 110. Cache memories are typically organized into multiple levels depending upon relative proximity to the processing circuitry. Alternatively, some, or all, of the cache for the processor set may be located “off chip.” In some computing environments, processor set 110 may be designed for working with qubits and performing quantum computing.

Computer readable program instructions are typically loaded onto computer 101 to cause a series of operational steps to be performed by processor set 110 of computer 101 and thereby effect a computer-implemented method, such that the instructions thus executed will instantiate the methods specified in flowcharts and/or narrative descriptions of computer-implemented methods included in this document (collectively referred to as “the inventive methods”). These computer readable program instructions are stored in various types of computer readable storage media, such as cache 121 and the other storage media discussed below. The program instructions, and associated data, are accessed by processor set 110 to control and direct performance of the inventive methods. In computing environment 100, at least some of the instructions for performing the inventive methods may be stored in block 200 in persistent storage 113.

COMMUNICATION FABRIC 111 is the signal conduction path that allows the various components of computer 101 to communicate with each other. Typically, this fabric is made of switches and electrically conductive paths, such as the switches and electrically conductive paths that make up busses, bridges, physical input/output ports and the like. Other types of signal communication paths may be used, such as fiber optic communication paths and/or wireless communication paths.

VOLATILE MEMORY 112 is any type of volatile memory now known or to be developed in the future. Examples include dynamic type random access memory (RAM) or static type RAM. Typically, volatile memory 112 is characterized by random access, but this is not required unless affirmatively indicated. In computer 101, the volatile memory 112 is located in a single package and is internal to computer 101, but, alternatively or additionally, the volatile memory may be distributed over multiple packages and/or located externally with respect to computer 101.

PERSISTENT STORAGE 113 is any form of non-volatile storage for computers that is now known or to be developed in the future. The non-volatility of this storage means that the stored data is maintained regardless of whether power is being supplied to computer 101 and/or directly to persistent storage 113. Persistent storage 113 may be a read only memory (ROM), but typically at least a portion of the persistent storage allows writing of data, deletion of data and re-writing of data. Some familiar forms of persistent storage include magnetic disks and solid state storage devices. Operating system 122 may take several forms, such as various known proprietary operating systems or open source Portable Operating System Interface-type operating systems that employ a kernel. The code included in block 200 typically includes at least some of the computer code involved in performing the inventive methods.

PERIPHERAL DEVICE SET 114 includes the set of peripheral devices of computer 101. Data communication connections between the peripheral devices and the other components of computer 101 may be implemented in various ways, such as Bluetooth connections, Near-Field Communication (NFC) connections, connections made by cables (such as universal serial bus (USB) type cables), insertion-type connections (for example, secure digital (SD) card), connections made through local area communication networks and even connections made through wide area networks such as the internet. In various embodiments, UI device set 123 may include components such as a display screen, speaker, microphone, wearable devices (such as goggles and smart watches), keyboard, mouse, printer, touchpad, game controllers, and haptic devices. Storage 124 is external storage, such as an external hard drive, or insertable storage, such as an SD card. Storage 124 may be persistent and/or volatile. In some embodiments, storage 124 may take the form of a quantum computing storage device for storing data in the form of qubits. In embodiments where computer 101 is required to have a large amount of storage (for example, where computer 101 locally stores and manages a large database) then this storage may be provided by peripheral storage devices designed for storing very large amounts of data, such as a storage area network (SAN) that is shared by multiple, geographically distributed computers. IoT sensor set 125 is made up of sensors that can be used in Internet of Things applications. For example, one sensor may be a thermometer and another sensor may be a motion detector.

NETWORK MODULE 115 is the collection of computer software, hardware, and firmware that allows computer 101 to communicate with other computers through WAN 102. Network module 115 may include hardware, such as modems or Wi-Fi signal transceivers, software for packetizing and/or de-packetizing data for communication network transmission, and/or web browser software for communicating data over the internet. In some embodiments, network control functions and network forwarding functions of network module 115 are performed on the same physical hardware device. In other embodiments (for example, embodiments that utilize software-defined networking (SDN)), the control functions and the forwarding functions of network module 115 are performed on physically separate devices, such that the control functions manage several different network hardware devices. Computer readable program instructions for performing the inventive methods can typically be downloaded to computer 101 from an external computer or external storage device through a network adapter card or network interface included in network module 115.

WAN 102 is any wide area network (for example, the internet) capable of communicating computer data over non-local distances by any technology for communicating computer data, now known or to be developed in the future. In some embodiments, the WAN 102 may be replaced and/or supplemented by local area networks (LANs) designed to communicate data between devices located in a local area, such as a Wi-Fi network. The WAN and/or LANs typically include computer hardware such as copper transmission cables, optical transmission fibers, wireless transmission, routers, firewalls, switches, gateway computers and edge servers.

END USER DEVICE (EUD) 103 is any computer system that is used and controlled by an end user (for example, a customer of an enterprise that operates computer 101), and may take any of the forms discussed above in connection with computer 101. EUD 103 typically receives helpful and useful data from the operations of computer 101. For example, in a hypothetical case where computer 101 is designed to provide a recommendation to an end user, this recommendation would typically be communicated from network module 115 of computer 101 through WAN 102 to EUD 103. In this way, EUD 103 can display, or otherwise present, the recommendation to an end user. In some embodiments, EUD 103 may be a client device, such as thin client, heavy client, mainframe computer, desktop computer and so on.

REMOTE SERVER 104 is any computer system that serves at least some data and/or functionality to computer 101. Remote server 104 may be controlled and used by the same entity that operates computer 101. Remote server 104 represents the machine(s) that collect and store helpful and useful data for use by other computers, such as computer 101. For example, in a hypothetical case where computer 101 is designed and programmed to provide a recommendation based on historical data, then this historical data may be provided to computer 101 from remote database 130 of remote server 104.

PUBLIC CLOUD 105 is any computer system available for use by multiple entities that provides on-demand availability of computer system resources and/or other computer capabilities, especially data storage (cloud storage) and computing power, without direct active management by the user. Cloud computing typically leverages sharing of resources to achieve coherence and economics of scale. The direct and active management of the computing resources of public cloud 105 is performed by the computer hardware and/or software of cloud orchestration module 141. The computing resources provided by public cloud 105 are typically implemented by virtual computing environments that run on various computers making up the computers of host physical machine set 142, which is the universe of physical computers in and/or available to public cloud 105. The virtual computing environments (VCEs) typically take the form of virtual machines from virtual machine set 143 and/or containers from container set 144. It is understood that these VCEs may be stored as images and may be transferred among and between the various physical machine hosts, either as images or after instantiation of the VCE. Cloud orchestration module 141 manages the transfer and storage of images, deploys new instantiations of VCEs and manages active instantiations of VCE deployments. Gateway 140 is the collection of computer software, hardware, and firmware that allows public cloud 105 to communicate through WAN 102.

Some further explanation of virtualized computing environments (VCEs) will now be provided. VCEs can be stored as “images.” A new active instance of the VCE can be instantiated from the image. Two familiar types of VCEs are virtual machines and containers. A container is a VCE that uses operating-system-level virtualization. This refers to an operating system feature in which the kernel allows the existence of multiple isolated user-space instances, called containers. These isolated user-space instances typically behave as real computers from the point of view of programs running in them. A computer program running on an ordinary operating system can utilize all resources of that computer, such as connected devices, files and folders, network shares, CPU power, and quantifiable hardware capabilities. However, programs running inside a container can only use the contents of the container and devices assigned to the container, a feature which is known as containerization.

PRIVATE CLOUD 106 is similar to public cloud 105, except that the computing resources are only available for use by a single enterprise. While private cloud 106 is depicted as being in communication with WAN 102, in other embodiments a private cloud may be disconnected from the internet entirely and only accessible through a local/private network. A hybrid cloud is a composition of multiple clouds of different types (for example, private, community or public cloud types), often respectively implemented by different vendors. Each of the multiple clouds remains a separate and discrete entity, but the larger hybrid cloud architecture is bound together by standardized or proprietary technology that enables orchestration, management, and/or data/application portability between the multiple constituent clouds. In this embodiment, public cloud 105 and private cloud 106 are both part of a larger hybrid cloud.

Exemplary Design Process Used in Semiconductor Design, Manufacture, and/or Test

One or more embodiments make use of computer-aided semiconductor integrated circuit design simulation, test, layout, and/or manufacture. In this regard, FIG. 17 shows a block diagram of an exemplary design flow 700 used for example, in semiconductor IC logic design, simulation, test, layout, and manufacture. Design flow 700 includes processes, machines and/or mechanisms for processing design structures or devices to generate logically or otherwise functionally equivalent representations of design structures and/or devices, such as those that can be analyzed using techniques disclosed herein or the like. The design structures processed and/or generated by design flow 700 may be encoded on machine-readable storage media to include data and/or instructions that when executed or otherwise processed on a data processing system generate a logically, structurally, mechanically, or otherwise functionally equivalent representation of hardware components, circuits, devices, or systems. Machines include, but are not limited to, any machine used in an IC design process, such as designing, manufacturing, or simulating a circuit, component, device, or system. For example, machines may include: lithography machines, machines and/or equipment for generating masks (e.g. e-beam writers), computers or equipment for simulating design structures, any apparatus used in the manufacturing or test process, or any machines for programming functionally equivalent representations of the design structures into any medium (e.g. a machine for programming a programmable gate array).

Design flow 700 may vary depending on the type of representation being designed. For example, a design flow 700 for building an application specific IC (ASIC) may differ from a design flow 700 for designing a standard component or from a design flow 700 for instantiating the design into a programmable array, for example a programmable gate array (PGA) or a field programmable gate array (FPGA) offered by Altera® Inc. or Xilinx® Inc.

FIG. 17 illustrates multiple such design structures including an input design structure 720 that is preferably processed by a design process 710. Design structure 720 may be a logical simulation design structure generated and processed by design process 710 to produce a logically equivalent functional representation of a hardware device. Design structure 720 may also or alternatively comprise data and/or program instructions that when processed by design process 710, generate a functional representation of the physical structure of a hardware device. Whether representing functional and/or structural design features, design structure 720 may be generated using electronic computer-aided design (ECAD) such as implemented by a core developer/designer. When encoded on a gate array or storage medium or the like, design structure 720 may be accessed and processed by one or more hardware and/or software modules within design process 710 to simulate or otherwise functionally represent an electronic component, circuit, electronic or logic module, apparatus, device, or system. As such, design structure 720 may comprise files or other data structures including human and/or machine-readable source code, compiled structures, and computer executable code structures that when processed by a design or simulation data processing system, functionally simulate or otherwise represent circuits or other levels of hardware logic design. Such data structures may include hardware-description language (HDL) design entities or other data structures conforming to and/or compatible with lower-level HDL design languages such as Verilog and VHDL, and/or higher level design languages such as C or C++.

Design process 710 preferably employs and incorporates hardware and/or software modules for synthesizing, translating, or otherwise processing a design/simulation functional equivalent of components, circuits, devices, or logic structures to generate a Netlist 780 which may contain design structures such as design structure 720. Netlist 780 may comprise, for example, compiled or otherwise processed data structures representing a list of wires, discrete components, logic gates, control circuits, I/O devices, models, etc. that describes the connections to other elements and circuits in an integrated circuit design. Netlist 780 may be synthesized using an iterative process in which netlist 780 is resynthesized one or more times depending on design specifications and parameters for the device. As with other design structure types described herein, netlist 780 may be recorded on a machine-readable data storage medium or programmed into a programmable gate array. The medium may be a nonvolatile storage medium such as a magnetic or optical disk drive, a programmable gate array, a compact flash, or other flash memory. Additionally, or in the alternative, the medium may be a system or cache memory, buffer space, or other suitable memory.

Design process 710 may include hardware and software modules for processing a variety of input data structure types including Netlist 780. Such data structure types may reside, for example, within library elements 730 and include a set of commonly used elements, circuits, and devices, including models, layouts, and symbolic representations, for a given manufacturing technology (e.g., different technology nodes, 32 nm, 45 nm, 90 nm, etc.). The data structure types may further include design specifications 740, characterization data 750, verification data 760, design rules 770, and test data files 785 which may include input test patterns, output test results, and other testing information. Design process 710 may further include, for example, standard mechanical design processes such as stress analysis, thermal analysis, mechanical event simulation, process simulation for operations such as casting, molding, and die press forming, etc. One of ordinary skill in the art of mechanical design can appreciate the extent of possible mechanical design tools and applications used in design process 710 without deviating from the scope and spirit of the invention. Design process 710 may also include modules for performing standard circuit design processes such as timing analysis, verification, design rule checking, place and route operations, etc.

Design process 710 employs and incorporates logic and physical design tools such as HDL compilers and simulation model build tools to process design structure 720 together with some or all of the depicted supporting data structures along with any additional mechanical design or data (if applicable), to generate a second design structure 790. Design structure 790 resides on a storage medium or programmable gate array in a data format used for the exchange of data of mechanical devices and structures (e.g. information stored in an IGES, DXF, Parasolid XT, JT, DRG, or any other suitable format for storing or rendering such mechanical design structures). Similar to design structure 720, design structure 790 preferably comprises one or more files, data structures, or other computer-encoded data or instructions that reside on data storage media and that when processed by an ECAD system generate a logically or otherwise functionally equivalent form of one or more IC designs or the like. In one embodiment, design structure 790 may comprise a compiled, executable HDL simulation model that functionally simulates the devices to be analyzed.

Design structure 790 may also employ a data format used for the exchange of layout data of integrated circuits and/or symbolic data format (e.g. information stored in a GDSII (GDS2), GLI, OASIS, map files, or any other suitable format for storing such design data structures). Design structure 790 may comprise information such as, for example, symbolic data, map files, test data files, design content files, manufacturing data, layout parameters, wires, levels of metal, vias, shapes, data for routing through the manufacturing line, and any other data required by a manufacturer or other designer/developer to produce a device or structure as described herein (e.g., .lib files). Design structure 790 may then proceed to a stage 795 where, for example, design structure 790: proceeds to tape-out, is released to manufacturing, is released to a mask house, is sent to another design house, is sent back to the customer, etc.

The illustrations of embodiments described herein are intended to provide a general understanding of the various embodiments, and they are not intended to serve as a complete description of all the elements and features of apparatus and systems that might make use of the circuits and techniques described herein. Many other embodiments will become apparent to those skilled in the art given the teachings herein; other embodiments are utilized and derived therefrom, such that structural and logical substitutions and changes can be made without departing from the scope of this disclosure. It should also be noted that, in some alternative implementations, some of the steps of the exemplary methods may occur out of the order noted in the figures. For example, two steps shown in succession may, in fact, be executed substantially concurrently, or certain steps may sometimes be executed in the reverse order, depending upon the functionality involved. The drawings are also merely representational and are not drawn to scale. Accordingly, the specification and drawings are to be regarded in an illustrative rather than a restrictive sense.

Embodiments are referred to herein, individually and/or collectively, by the term “embodiment” merely for convenience and without intending to limit the scope of this application to any single embodiment or inventive concept if more than one is, in fact, shown. Thus, although specific embodiments have been illustrated and described herein, it should be understood that an arrangement achieving the same purpose can be substituted for the specific embodiment(s) shown; that is, this disclosure is intended to cover any and all adaptations or variations of various embodiments. Combinations of the above embodiments, and other embodiments not specifically described herein, will become apparent to those of skill in the art given the teachings herein.

The terminology used herein is for the purpose of describing particular embodiments only and is not intended to be limiting. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, steps, operations, elements, and/or components, but do not preclude the presence or addition of one or more other features, steps, operations, elements, components, and/or groups thereof. Terms such as “bottom”, “top”, “above”, “over”, “under” and “below” are used to indicate relative positioning of elements or structures to each other as opposed to relative elevation. If a layer of a structure is described herein as “over” another layer, it will be understood that there may or may not be intermediate elements or layers between the two specified layers. If a layer is described as “directly on” another layer, direct contact of the two layers is indicated. As the term is used herein and in the appended claims, “about” means within plus or minus ten percent.

The corresponding structures, materials, acts, and equivalents of any means or step-plus-function elements in the claims below are intended to include any structure, material, or act for performing the function in combination with other claimed elements as specifically claimed. The description of the various embodiments has been presented for purposes of illustration and description, but is not intended to be exhaustive or limited to the forms disclosed. Many modifications and variations will be apparent to those of ordinary skill in the art without departing from the scope and spirit thereof. The embodiments were chosen and described in order to best explain principles and practical applications, and to enable others of ordinary skill in the art to understand the various embodiments with various modifications as are suited to the particular use contemplated.

The abstract is provided to comply with 37 C.F.R. § 1.76 (b), which requires an abstract that will allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in a single embodiment for the purpose of streamlining the disclosure. This method of disclosure is not to be interpreted as reflecting an intention that the claimed embodiments require more features than are expressly recited in each claim. Rather, as the appended claims reflect, the claimed subject matter may lie in less than all features of a single embodiment. Thus, the following claims are hereby incorporated into the Detailed Description, with each claim standing on its own as separately claimed subject matter.

Given the teachings provided herein, one of ordinary skill in the art will be able to contemplate other implementations and applications of the techniques and disclosed embodiments. Although illustrative embodiments have been described herein with reference to the accompanying drawings, it is to be understood that illustrative embodiments are not limited to those precise embodiments, and that various other changes and modifications are made therein by one skilled in the art without departing from the scope of the appended claims.

What is claimed is:

1. A magnetoresistive random-access memory cell, comprising:
a first magnetic layer having a first lattice constant;
a second magnetic layer having a second lattice constant;
a tunnel barrier between the first and second magnetic layers, wherein the tunnel barrier includes at least one oxide layer with an oxide layer lattice constant, wherein the oxide layer lattice constant has a mismatch smaller than six percent with at least one of the first and second lattice constants.

2. The magnetoresistive random access memory cell of claim 1, further comprising a templating layer, wherein at least one of the magnetic layers comprises a perpendicularly-magnetized Heusler compound grown on the templating layer, wherein the oxide layer lattice constant has the mismatch smaller than six percent with the at least one of the magnetic layers that comprises the perpendicularly-magnetized Heusler compound grown on the templating layer.

3. The magnetoresistive random access memory cell of claim 2, wherein the at least one of the magnetic layers that comprises the perpendicularly-magnetized Heusler compound grown on the templating layer comprises a free layer.

4. The magnetoresistive random access memory cell of claim 1, wherein the tunnel barrier includes only the at least one oxide layer.

5. The magnetoresistive random access memory cell of claim 4, wherein the first magnetic layer and the second magnetic layer each include a perpendicularly-magnetized Heusler compound.

6. The magnetoresistive random access memory cell of claim 5, wherein the first magnetic layer and the second magnetic layer are selected from the group consisting of Mn₃Ge, Mn₃Sn, Mn₃Sb, Mn₂CoSn, Mn₂FeSb, Mn₂CoAl, Mn₂CoGe, Mn₂CoSi, and Mn₂CuSi.

7. The magnetoresistive random access memory cell of claim 4, wherein one of the first magnetic layer and the second magnetic layer includes a perpendicularly-magnetized Heusler compound and wherein another one of the first magnetic layer and the second magnetic layer includes a cubic-based magnetic material.

8. The magnetoresistive random access memory cell of claim 7, wherein the one of the first magnetic layer and the second magnetic layer is selected from the group consisting of Mn₃Ge, Mn₃Sn, Mn₃Sb, Mn₂CoSn, Mn₂FeSb, Mn₂CoAl, Mn₂CoGe, Mn₂CoSi, and Mn₂CuSi and wherein the another one of the first magnetic layer and the second magnetic layer is selected from the group consisting of Fe, Co—Fe, Co—Fe—B, Fe—B and Co—Mn.

9. The magnetoresistive random access memory cell of claim 4, wherein the tunnel barrier is selected from the group consisting of SrO and BaO.

10. The magnetoresistive random access memory cell of claim 1, wherein:
the at least one oxide layer comprises a first oxide layer;
the oxide layer lattice constant comprises a first oxide layer lattice constant; and
the tunnel barrier further includes a second oxide layer with a second oxide layer lattice constant.

11. The magnetoresistive random access memory cell of claim 10, wherein the first magnetic layer and the second magnetic layer each include a perpendicularly-magnetized Heusler compound, one of which is a free layer and another of which is a fixed layer.

12. The magnetoresistive random access memory cell of claim 11, wherein the first magnetic layer and the second magnetic layer are selected from the group consisting of Mn₃Ge, Mn₃Sn, Mn₃Sb, Mn₂CoSn, Mn₂FeSb, Mn₂CoAl, Mn₂CoGe, Mn₂CoSi, and Mn₂CuSi.

13. The magnetoresistive random access memory cell of claim 10, wherein one of the first magnetic layer and the second magnetic layer includes a perpendicularly-magnetized Heusler compound and wherein another one of the first magnetic layer and the second magnetic layer includes a cubic-based magnetic material.

14. The magnetoresistive random access memory cell of claim 13, wherein the one of the first magnetic layer and the second magnetic layer is selected from the group consisting of Mn₃Ge, Mn₃Sn, Mn₃Sb, Mn₂CoSn, Mn₂FeSb, Mn₂CoAl, Mn₂CoGe, Mn₂CoSi, and Mn₂CuSi and wherein the another one of the first magnetic layer and the second magnetic layer is selected from the group consisting of Fe, Co—Fe, Co—Fe—B, Fe—B and Co—Mn.

15. The magnetoresistive random access memory cell of claim 10, wherein one of the first oxide layer and the second oxide layer is selected from the group consisting of SrO and BaO and another one of the first oxide layer and the second oxide layer is MgO.

16. The magnetoresistive random access memory cell of claim 15, wherein:
at least one of the first magnetic layer and the second magnetic layer includes a perpendicularly-magnetized Heusler compound; and
the one of the first oxide layer and the second oxide layer that is selected from the group consisting of SrO and BaO is in direct contact with the at least one of the first magnetic layer and the second magnetic layer that includes the perpendicularly-magnetized Heusler compound.

17. A magnetoresistive random-access memory array, comprising:
a plurality of bit lines and a plurality of complementary bit lines forming a plurality of bit line-complementary bit line pairs;
a plurality of word lines intersecting the plurality of bit line pairs at a plurality of cell locations;
a plurality of magnetoresistive random-access memory cells located at each of the plurality of cell locations, each of the magnetoresistive random-access memory cells being electrically connected to a corresponding bit line and selectively interconnected to a corresponding one of the complementary bit lines under control of a corresponding one of the word lines, each of the plurality of magnetoresistive random-access memory cells comprising:
a first magnetic layer having a first lattice constant;
a second magnetic layer having a second lattice constant; and
a tunnel barrier between the first and second magnetic layers, wherein the tunnel barrier includes at least one oxide layer with an oxide layer lattice constant, wherein the oxide layer lattice constant has a mismatch smaller than six percent with at least one of the first and second lattice constants.

18. The magnetoresistive random-access memory array of claim 17, wherein each of the plurality of magnetoresistive random-access memory cells further comprises a templating layer, wherein at least one of the magnetic layers comprises a perpendicularly-magnetized Heusler compound grown on the templating layer, wherein the oxide layer lattice constant has the mismatch smaller than six percent with the at least one of the magnetic layers that comprises the perpendicularly-magnetized Heusler compound grown on the templating layer.

19. The magnetoresistive random-access memory array of claim 18, wherein the at least one of the magnetic layers that comprises the perpendicularly-magnetized Heusler compound grown on the templating layer comprises a free layer.

20. The magnetoresistive random-access memory array of claim 17, wherein the tunnel barrier includes only the at least one oxide layer.

21. The magnetoresistive random-access memory array of claim 17, wherein:
the at least one oxide layer comprises a first oxide layer;
the oxide layer lattice constant comprises a first oxide layer lattice constant; and
the tunnel barrier further includes a second oxide layer with a second oxide layer lattice constant.

22. The magnetoresistive random-access memory array of claim 21, wherein the first magnetic layer and the second magnetic layer each include a perpendicularly-magnetized Heusler compound, one of which is a free layer and another of which is a fixed layer.

23. A method of forming a magnetoresistive random-access memory cell, comprising:
providing a substrate;
forming a first magnetic layer outward of the substrate, the first magnetic layer having a first lattice constant;
forming a tunnel barrier outward of the first magnetic layer, wherein the tunnel barrier includes at least one oxide layer with an oxide layer lattice constant; and
forming a second magnetic layer outward of the tunnel barrier, the second magnetic layer having a second lattice constant;
wherein the oxide layer is formed such that the oxide layer lattice constant has a mismatch smaller than six percent with at least one of the first and second lattice constants.

24. A hardware description language (HDL) design structure encoded on a machine-readable data storage medium, the HDL design structure comprising elements that when processed in a computer-aided design system generates a machine-executable representation of a magnetoresistive random-access memory cell, wherein the magnetoresistive random-access memory cell comprises:
a first magnetic layer having a first lattice constant;
a second magnetic layer having a second lattice constant;
a tunnel barrier between the first and second magnetic layers, wherein the tunnel barrier includes at least one oxide layer with an oxide layer lattice constant, wherein the oxide layer lattice constant has a mismatch smaller than six percent with at least one of the first and second lattice constants.

25. A hardware description language (HDL) design structure encoded on a machine-readable data storage medium, the HDL design structure comprising elements that when processed in a computer-aided design system generates a machine-executable representation of a magnetoresistive random-access memory array, wherein the magnetoresistive random-access memory array comprises:
a plurality of bit lines and a plurality of complementary bit lines forming a plurality of bit line-complementary bit line pairs;
a plurality of word lines intersecting the plurality of bit line pairs at a plurality of cell locations;
a plurality of magnetoresistive random-access memory cells located at each of the plurality of cell locations, each of the magnetoresistive random-access memory cells being electrically connected to a corresponding bit line and selectively interconnected to a corresponding one of the complementary bit lines under control of a corresponding one of the word lines, each of the plurality of magnetoresistive random-access memory cells comprising:
a first magnetic layer having a first lattice constant;
a second magnetic layer having a second lattice constant; and
a tunnel barrier between the first and second magnetic layers, wherein the tunnel barrier includes at least one oxide layer with an oxide layer lattice constant, wherein the oxide layer lattice constant has a mismatch smaller than six percent with at least one of the first and second lattice constants.
